(19) United States
(12) Patent Application Publication
(10) Pub. No.: US 2026/0033095 A1
(43) Pub. Date: Jan. 29, 2026

(54) DISPLAY DEVICE

(71) Applicant: LG Display Co., Ltd., Seoul (KR)

(72) Inventors: Dae Han WON, Paju-si (KR); Kyoung June JUNG, Paju-si (KR); Chan Woo IM, Paju-si (KR); Jeen Wook KWON, Paju-si (KR)

(73) Assignee: LG Display Co., Ltd., Seoul (KR)

(21) Appl. No.: 19/255,132

(22) Filed: Jun. 30, 2025

(30) Foreign Application Priority Data
Jul. 25, 2024 (KR) 10-2024-0098726

(51) Int. Cl. H10H 29/80; G06F 1/16; H10H 29/39; H10H 29/855

(52) U.S. Cl. CPC H10H 29/842; G06F 1/1652; H10H 29/39; H10H 29/8323; H10H 29/8552

(57) ABSTRACT

The disclosure discloses a display device. The disclosure includes a substrate, a circuit layer on the substrate, and a plurality of banks on the circuit layer. One or more light-emitting elements, each having a first electrode and a second electrode, are disposed one-to-one on the banks. A contact electrode is on the circuit layer, spaced apart from the banks. A first optical layer covers the banks and the light-emitting elements on the banks. A second optical layer covers the first optical layer and includes a contact hole that exposes a portion of the contact electrode. The structure is configured such that, when the distance between the bank and the first optical layer on a surface of the circuit layer is defined as 1, the distance between the first optical layer and the contact hole on the same surface ranges from 0.5 to 2.5, thereby supporting improved structural integrity and reliability.

### CROSS-REFERENCE TO RELATED APPLICATION

This application claims priority to and the benefit of Korean Patent Application No. 10-2024-0098726, filed on Jul. 25, 2024, the disclosure of which is incorporated herein by reference in its entirety for all purposes.

### BACKGROUND

### Technical Field

The present disclosure relates to a display device.

### Description of the Related Art

Examples of a display device include organic light-emitting diode (OLED) display devices that emit light by itself, liquid crystal display (LCD) devices that require separate light sources, etc.

Recently, display devices including inorganic light-emitting diodes (LEDs) have been attracting attention as next-generation display devices. Since an inorganic LED is formed of an inorganic material rather than an organic material, the display devices including the inorganic LED have a faster turn-on speed, better luminous efficiency, and higher luminance images than LCD devices or OLED display devices.

### BRIEF SUMMARY

The disclosure relates to a flexible display device using micro light emitting diode technology, featuring structural configurations that enhance durability and performance. A primary feature involves the design of contact holes that connect a contact electrode to another electrode. The cross-sectional structure and spatial arrangement of these holes are specifically configured to reduce mechanical stress and reduce the likelihood of cracking. This is achieved by establishing a defined distance ratio between a bank structure and the contact hole on a circuit layer, which supports structural integrity during bending.

The disclosure also includes conductive lines in a bending area that are patterned in shapes such as zigzag or wave forms to distribute mechanical stress more evenly. These lines are formed from materials with high ductility, such as gold or copper, to maintain electrical connectivity under deformation. The device uses a multilayer arrangement of insulating and protective films, with selected regions modified or removed to accommodate bending while maintaining electrical and mechanical stability. Additionally, a compact micro driver circuit is used to control individual or grouped micro light emitting elements, simplifying the circuit layout and supporting efficient operation. These configurations together support a high luminance, mechanically reliable display suitable for flexible applications.

Embodiments of the present disclosure are directed to providing a display device in which a cross-sectional structure of a contact hole, used to connect a contact electrode to a cathode, is modified to prevent or reduce cracking of the cathode during the connection process.

Technical benefits of embodiments of the present disclosure are not limited to the above-described benefit, and other benefits that are not mentioned will be able to be clearly understood by those skilled in the art from the following description.

According to an embodiment of the present disclosure, there is provided a display device including a substrate, a circuit layer disposed on the substrate, a plurality of banks disposed on the circuit layer, one or more light-emitting elements disposed one-to-one on the banks and each having a first electrode and a second electrode, a contact electrode disposed on the circuit layer to be spaced apart from the banks, a first optical layer covering the banks and the one or more light-emitting elements disposed on the banks, and a second optical layer covering the first optical layer and having a contact hole exposing a part of the contact electrode, wherein when a distance between the bank and the first optical layer on a surface of the circuit layer is defined as a reference value of 1, a distance between the first optical layer and the contact hole on the surface of the circuit layer ranges from 0.5 to 2.5.

Detailed items according to various examples of the present disclosure other than the above-described configuration are included in the following description and the accompanying drawings.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is an exploded perspective view of a display device according to one embodiment of the present disclosure;

FIG. 2 is a plan view of a display device according to one embodiment of the present disclosure;

FIG. 3 is an enlarged plan view of a connection structure of a display device according to one embodiment of the present disclosure;

FIG. 4 is a diagram illustrating a circuit structure according to an embodiment of the present disclosure.

FIG. 5 is a plan view of a display device according to one embodiment of the present disclosure;

FIG. 6 is a plan view of a display device according to an embodiment of the present disclosure.

FIG. 7 is a cross-sectional view of a display device according to an embodiment of the present disclosure.

FIG. 8 is an enlarged cross-sectional view of a display device according to an embodiment of the present disclosure.

FIG. 9 is an enlarged plan view of a part of a display device according to an embodiment of the present disclosure;

FIG. 10 is a cross-sectional view along lines II-II′ of FIG. 9 and a cross-sectional view of the display device according to an embodiment of the present disclosure;

FIG. 11 is an enlarged cross-sectional view of portion A in FIG. 10;

FIG. 12 is a cross-sectional view along lines II-II′ of FIG. 9 and is a cross-sectional view of a display device according to another embodiment of the present disclosure;

FIG. 13 is an enlarged cross-sectional view of portion B in FIG. 12;

FIGS. 14A to 14D are cross-sectional views of a manufacturing process of a display device according to an embodiment of the present disclosure;

FIGS. 15A to 15D are cross-sectional views of a manufacturing process of a display device according to another embodiment of the present disclosure;

FIG. 16 is a plan view illustrating a halftone mask when manufacturing the display device according to another embodiment of the present disclosure; and

FIGS. 17 to 20 are views illustrating devices to which the display devices according to the embodiments of the present disclosure are applied.

### DETAILED DESCRIPTION

The advantages and features of the present disclosure, and methods of achieving them will become apparent upon reference to the embodiments described in detail below in conjunction with the accompanying drawings. However, the present disclosure is not limited to the following embodiments disclosed herein, but may be implemented in various different forms; rather, the present embodiments are provided to make the disclosure of the present disclosure complete and to enable those skilled in the art to fully comprehend the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Identical reference numerals may designate identical components throughout the description. Further, in describing the present disclosure, detailed descriptions of related known technologies may be omitted or briefly described so as not to obscure the essence of the present disclosure. Terms such as, “including,” “comprising,” “containing,” “having,” “consisting of,” “constituted of,” or “comprising” as used herein are generally intended to allow for the addition of other components, unless the terms are used with the term such as “only,” “merely,” etc. References to components of a singular noun include the plural of that noun, unless specifically stated otherwise.

In the interpretation of components, they are construed to include margins of error or tolerance, even if not explicitly stated.

When describing a positional relationship, for example, “on,” “on top of,” “over,” “above,” “beneath,” “under,” “below,” “next to,” or “adjacent to” describes the positional relationship of two parts, one or more other parts may be located, disposed or interposed between the two parts, unless, “just,” “right,” “immediately,” “directly,” or “near to” is used. Furthermore, the terms “left,” “right,” “top,” “bottom, “downward,” “upward,” “upper,” “lower,” and the like refer to an arbitrary frame of reference. The term spatially relative should be understood to include different orientations of the element in use or operation in addition to the orientations shown in the drawings. For example, an element described as “below” or “beneath” another element may be placed “above” another element if the elements shown in the drawings are reversed. Thus, the exemplary term “down” may include both down and up directions.

When describing a temporal relationship, “after,” “following,” “subsequently to,” “next to,” or “before” describes a temporal antecedent or consequent relationship, which may not be continuous unless a term such as “just,” “immediately” or “directly” is used.

The first, the second, and so on are used to describe various components, but these components are not limited by these terms. These terms are used only to distinguish one component from another. Therefore, the first component referred to below may be a second component within the technical spirit of the present disclosure.

Terms such as first, second, A, B, (a), or (b) may be used to describe elements of the present disclosure. Such terms are intended only to distinguish one component from another and are not intended to define the nature, sequence, order, or number of such components.

When a component is described as being “connected,” “coupled,” “linked,” “adhered,” “accessed,” or “attached” to another component, it is to be understood that the component may be directly connected, coupled, accessed, linked, adhered or attached to the other component, but that there may also be other components interposed between the respective components which may be indirectly connected, coupled, linked, adhered accessed, or attached, unless specifically stated otherwise.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When a component is described as being “in contacted” or “overlapped” with another component, it is to be understood that the component may be in direct contacted or overlap with the other component, but that there may also be other components “located,” “disposed” or “interposed” between the respective components which may be in direct or indirect contacted or overlap with, unless specifically stated otherwise.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms the first direction, the second direction, the third direction, the X-axis direction, the Y-axis direction, and the Z-axis direction are not to be interpreted solely as a geometric relationship in which the relationship to one another is perpendicular, but may refer to a broader range of orientations in which the configurations of the present disclosure may function.

Each of the features of various embodiments of the present disclosure may be coupled or combined with one another in whole or in part, and may be technologically interlocked and operated in various ways, and each of the embodiments may be carried out independently or in conjunction with one another.

Hereinafter, various embodiments of the present disclosure will be described in detail with reference to the accompanying drawings.

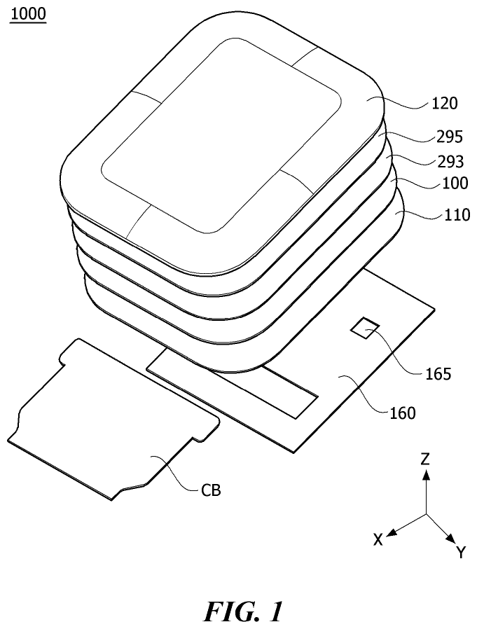

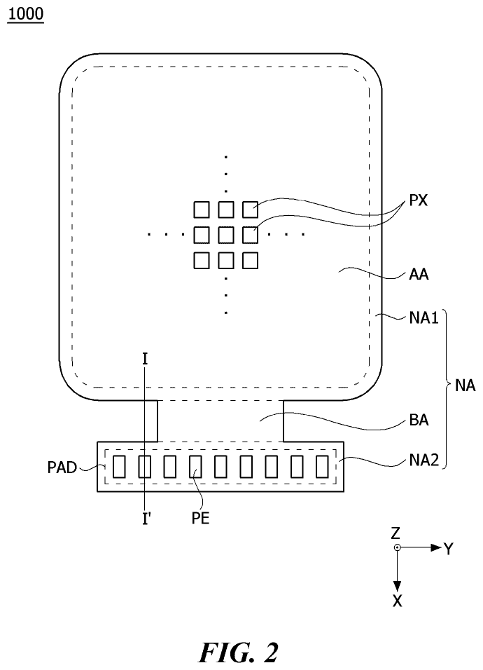

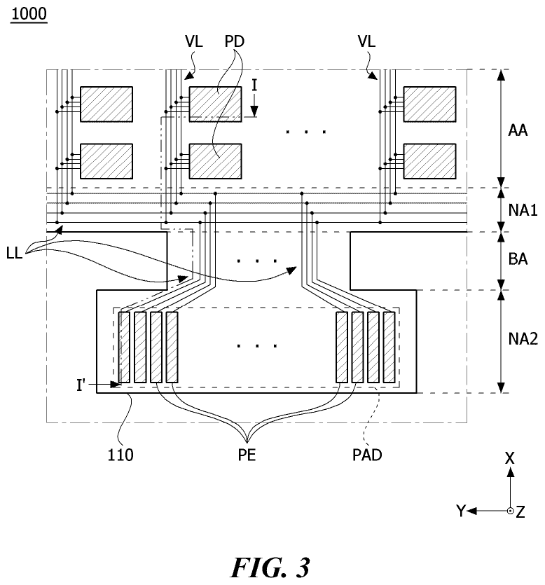

FIG. 1 is an exploded perspective view of a display device according to one embodiment of the present disclosure; FIG. 2 is a plan view of a display device according to one embodiment of the present disclosure; FIG. 3 is an enlarged plan view of a connection structure of a display device according to one embodiment of the present disclosure.

Referring to FIGS. 1 to 3, a display device 1000 according to one embodiment of the present disclosure may include a display panel 100, a polarizing layer 293, an adhesive layer 295, a cover member 120, a support substrate 110, a flexible circuit board CB, and a printed circuit board 160, but the present disclosure is not limited thereto. For example, one or more of the above-described components or layers can be omitted, integrated or each include one or more sub-components or sub-layers. Alternatively, the display device 1000 can include more or less components or layers than described.

For example, the display device 1000 may include a substrate 110. The substrate 110 may be a member that supports other components of the display device 1000. The substrate 110 may be made of an insulating material. For example, the substrate 110 may be made of glass, resin, or the like. Additionally, the substrate 110 may be made of a material having flexibility. For example, the substrate 110 may be made of a flexible plastic material such as polyimide (PI), polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA), and polystyrene (PS) or the like. However, the embodiments of the present disclosure are not limited thereto.

The display panel 100 may implement information, video, and/or an image provided to a user. For example, the display panel 100 may include a display area AA and a non-display area NA. The non-display area NDA may be an area outside of the display area DA (for example, in the vicinity of the display area DA or entirely or partly surrounding the display area DA), and may also be referred to as an edge area or a bezel area. The non-display area NDA may include a plurality of adjacent or separate non-display areas. For example, the substrate 110 may include the display area AA and the non-display area NA. The display area AA and non-display area NA are not limited to being described only with respect to the substrate 110 but may be described throughout the entire display device 1000.

The display area AA may be an area in which an image is displayed. The display area AA may include a plurality of pixels PX. Each of the plurality of pixels PX may be composed of a plurality of sub-pixels (for example, two, three or more). A plurality of micro-LEDs may be respectively arranged in the plurality of sub-pixels. The plurality of micro-LEDs may be configured differently depending on the type of display device 1000. For example, when the display device 1000 is an inorganic light emitting display device, the light emitting element may be a light-emitting diode (LED), a micro light-emitting diode (Micro-LED), or a mini-light-emitting diode (MLED), but embodiments of the present disclosure are not limited thereto.

The non-display area NA may be an area in which no information, image or video is displayed. Various lines and/or circuits for driving the plurality of pixels PX of the display area AA may be positioned in the non-display area NA. For example, in the non-display area NA, various lines and/or driving circuits may be mounted, and a pad portion PAD to which an integrated circuit, a printed circuit, and the like are connected may be provided, but the embodiments of the present disclosure are not limited thereto.

For example, the driving circuit may be a data driving circuit, a touch sense driving circuit and/or a gate driving circuit, but the embodiments of the present disclosure are not limited thereto. Lines through which a control signal for controlling the driving circuits is supplied may be provided. For example, the control signal may include various timing signals including a clock signal, an input data enable signal, and synchronization signals such as horizontal synchronization signals or vertical synchronization signals, but the embodiments of the present disclosure are not limited thereto. The control signal may be received through the pad portion PAD and/or lines and/or layers. For example, link lines LL for transmitting signals may be positioned in the non-display area NA. For example, the pad portion PAD may be connected to driving components such as the flexible circuit board CB and the printed circuit board 160.

According to the present disclosure, the non-display area NA may include a first non-display area NA1, a bending area BA, and a second non-display area NA2. For example, the first non-display area NA1 may be an area that surrounds at least a portion of the display area AA. The bending area BA may be an area extending from at least one of the plurality of sides of the first non-display area NA1, and may be a bendable area. The second non-display area NA2 may be an area extending from the bending area BA along a direction opposite to the first non-display area NA1, and the pad portion PAD may be positioned in the second non-display area NA2. For example, the bending area BA may be in a bent state, and the remaining area of the substrate 110, excluding the bending area BA, may be in a flat state. In this case, as the bending area BA is in a bent state, the second non-display area NA2 may be positioned on the rear surface of the display area AA. However, the embodiments of the present disclosure are not limited thereto.

The display area AA of the substrate 110 or the display device 1000 may be configured in various shapes depending on the design of the display device 1000. For example, the display area AA may be configured in a rectangular shape with four rounded corners, but the embodiments of the present disclosure are not limited thereto. In another example, the display area AA may be configured in a rectangular shape with four right-angled corners, a circular shape, an elliptic shape, an oval shape, a polygon shape (e.g., a hexagon) or the like, but the embodiments of the present disclosure are not limited thereto.

According to the present disclosure, the width of the second non-display area NA2 in which a plurality of pad electrodes PE are arranged may be greater than the width of the bending area BA in which only the plurality of link lines LL are arranged. Additionally, the width of the display area AA in which the plurality of sub-pixels are arranged may be greater than the width of the bending area BA in which only the plurality of link lines LL are arranged. In the drawings, the width of the bending area BA is illustrated as being smaller than that of other areas of the substrate 110. However, the shape of the substrate 110 including the bending area BA is merely exemplary, and the embodiments of the present disclosure are not limited thereto.

Referring to FIG. 2, in the display device according to an exemplary configuration of the present disclosure, a display area AA in which a plurality of pixels PX are disposed and a first non-display area NA1 surrounding the display area AA may be disposed.

Referring to FIG. 3, a plurality of pixel driving circuits PD may be arranged in the display area AA. The plurality of pixel driving circuits PD may be circuits for driving the micro-LEDs of the plurality of sub-pixels. Each pixel driving circuit PD may drive the driving light-emitting elements of at least one sub-pixel. Each of the plurality of pixel driving circuits PD may include a plurality of transistors including a driving transistor, at least one storage capacitor, and the like and may supply a control signal, power, voltage (e.g., high potential voltage, low potential voltage) and a driving current to the micro-LEDs of the plurality of sub-pixel to control the light emission operation of the plurality of micro-LEDs. For example, the pixel driving circuit PD may include a power line and a signal line for controlling the on/off state and/or light emission time of the micro-LED. For example, the plurality of pixel driving circuits PD may be a driving driver manufactured using a metal-oxide-silicon field effect transistor (MOSFET) fabrication process on a semiconductor substrate, but the embodiments of the present disclosure are not limited thereto. The driving driver may include the plurality of pixel driving circuits PD and may drive the plurality of sub-pixels.

Referring also to FIG. 1, the flexible circuit board CB and the printed circuit board 160 may be positioned below the display panel 100. The flexible circuit board CB and the printed circuit board 160 may be positioned on or attached to at least one edge of the display panel 100, but the embodiments of the present disclosure are not limited thereto.

One side of the flexible circuit board CB may be attached to the display panel 100, and the other side thereof may be attached to the printed circuit board 160, but embodiments of the present disclosure are not limited thereto. The flexible circuit board CB may be a flexible film, but embodiments of the present disclosure are not limited thereto. For example, the flexible circuit board CB may alternatively be a flexible flat cable (FFC) or a flexible printed circuit (FPC).

The pad portion PAD including the plurality of pad electrodes PE may be positioned in the second non-display area NA2. Driving components, including one or more flexible circuit boards (or flexible films) CB and the printed circuit board 160, may be attached or bonded to the pad portion PAD. The plurality of pad electrodes PE of the pad portion PAD may be electrically connected to the one or more flexible circuit boards (or flexible films) CB, and may transmit various signals (or power, voltage, current) from the printed circuit board 160 and/or the flexible circuit board (or flexible film) CB to the plurality of pixel driving circuits PD of display area AA.

The flexible circuit board (or flexible film) CB may be a film in which various components are arranged on a base film having flexibility. For example, a driving IC, such as a gate driver IC, a data driver IC or a touch sensing driver IC, may be positioned on the flexible circuit board (or flexible film) CB, but the embodiments of the present disclosure are not limited thereto.

The driving IC may be a component that processes data and a driving signal for displaying an image. The driving IC may be disposed by a method such as a chip-on-glass (COG) method, a chip-on-film (COF) method, a chip on plastic (COP) method, a chip on plate (COP) method, or a tape carrier package (TCP) method depending on a method of being mounted, but embodiments of the present disclosure are not limited thereto. The flexible circuit board (or flexible film) CB may be attached to or bonded on the plurality of pad electrodes PE through a conductive adhesive layer, but embodiments of the present disclosure are not limited thereto.

The printed circuit board 160 may be a component electrically connected to one or more flexible circuit boards (or flexible films) CB and supplying signals to the driving IC. The printed circuit board 160 may be disposed at one side of the flexible circuit board (or flexible film) CB and electrically connected to the flexible circuit board (or flexible film) CB. Various components for supplying various signals (or power, voltage, current) to the driving IC may be disposed on the printed circuit board 160. For example, various components, such as a timing controller, a power supply unit, a memory, a processor, etc., may be disposed on the printed circuit board 160. For example, the printed circuit board 160 may include a power management integrated circuit (PMIC), but embodiments of the present disclosure are not limited thereto.

The printed circuit board 160 may include at least one hole 165, but the embodiments of the present disclosure are not limited thereto. An internal component for sensing ambient light, temperature, or humidity or the like, which may be provided to a plurality of sensors, may be positioned in a region corresponding to the at least one hole 165. For example, the internal component may include an ambient light sensor (ALS), a temperature sensor, or a humidity sensor or the like, but the embodiments of the present disclosure are not limited thereto. For example, the hole 165 may be a transmission hole or the like, but the embodiments of the present disclosure are not limited thereto.

Referring to FIG. 1, the polarizing layer 293 may be positioned on the display panel 100. The polarizing layer 293 may prevent or reduce light generated from an external light source from entering the interior of the display panel 100 and affecting the micro-LEDs or the like.

The cover member 120 may be positioned on the polarizing layer 293. The cover member 120 may be a member for protecting the display panel 100. The adhesive layer 295 may be positioned between the polarizing layer 293 and the cover member 120. The cover member 120 may be attached to the display panel 100 by using the adhesive layer 295. The adhesive layer 295 may include an optically clear adhesive (OCA), an optically clear resin (OCR), a pressure sensitive adhesive (PSA), a silicone resin, an epoxy resin, a UV curable resin, a polyimide resin, an acrylate resin, a polyurethane resin, and polydimethylsiloxane (PDMS), or the like, but the embodiments of the present disclosure are not limited thereto.

The support substrate 110 may be positioned between the display panel 100 and the printed circuit board 160. The support substrate 110 may reinforce the rigidity of the display panel 100. The support substrate 110 may be a back plate, but the embodiments of the present disclosure are not limited thereto.

Referring to FIGS. 1 to 3, the plurality of link lines LL may be arranged in the first and second non-display areas NA1 and NA2. The plurality of link lines LL may be lines for transmitting various signals (or power, voltage, current) from the one or more flexible circuit boards (or flexible films) CB and/or the printed circuit board 160 to the display area AA. The plurality of link lines LL may extend from the plurality of pad electrodes PE of the second non-display area NA2 toward the bending area BA and the first non-display area NA1, and may be electrically connected to a plurality of driving lines VL of the display area AA.

The plurality of pixel driving circuits PD may be driven by receiving signals (or power, voltage, current) from one or more flexible circuit boards (or flexible films) CB and/or the printed circuit board 160 through the driving line VL in the display area AA and the link line LL in the non-display area NA.

For example, a plurality of driving lines VL may be lines for transmitting a signal (or power, voltage, current) output from the flexible circuit board (or flexible film) CB and/or the printed circuit board 160 together with a plurality of link lines LL to each of a plurality of pixel driving circuits PD. A plurality of driving lines VL may be disposed in the display area AA and electrically connected to each of a plurality of pixel driving circuits PD. A plurality of driving lines VL may extend from the display area AA toward the non-display area NA and may be electrically connected to a plurality of link lines LL.

Therefore, the signal (or power, voltage, current) output from the flexible circuit board (or flexible film) CB and/or the printed circuit board 160 may be transmitted to each of the plurality of pixel driving circuits PD through the plurality of link lines LL and the plurality of driving lines VL.

As the bending area BA is bent, a portion of the plurality of link lines LL may also be bent together. Stress may be concentrated on a portion of the bent link lines LL, thereby causing cracks in the link lines LL. Accordingly, the plurality of link lines LL may be formed of a highly flexible conductive material to reduce cracks when the bending area BA is bent. For example, the plurality of link lines LL may be formed of a highly flexible conductive material, such as gold (Au), Copper (Cu), silver (Ag), or aluminum (Al), but the embodiments of the present disclosure are not limited thereto.

Additionally, the plurality of link lines LL may be formed of one of various conductive materials used in the display area AA. For example, the plurality of link lines LL may be made of molybdenum (Mo), chromium (Cr), titanium (Ti), nickel (Ni), neodymium (Nd), Gold (Au), aluminum (Al), copper (Cu), an alloy of silver (Ag) and magnesium (Mg), or other alloys thereof, but the embodiments of the present disclosure are not limited thereto. The plurality of link lines LL may have a multilayer structure made of various conductive materials. For example, the plurality of link lines LL may have a triple-layer structure of, e.g., titanium (Ti)/aluminum (Al)/titanium (Ti), aluminum (Al)/molybdenum titanium (MoTi)/aluminum (Al), etc., but the embodiments of the present disclosure are not limited thereto.

A plurality of link lines LL may be configured in various shapes to reduce stress. At least a portion of the plurality of link lines LL disposed on the bending area BA may extend in the same direction as the extending direction of the bending area BA, or may extend in a direction different from the extending direction of the bending area BA to reduce stress. For example, when the bending area BA extends in one direction from the first non-display area NA1 to the second non-display area NA2, at least a portion of the link line LL disposed on the bending area BA may extend in a direction inclined to the one direction.

For another example, at least a portion of the plurality of link lines LL may be configured in various shapes. For example, at least a portion of the plurality of link lines LL disposed on the bending area BA may have a shape in which a conductive pattern having at least one of a diamond shape, a rhombus shape, a trapezoidal shape, a triangular wave shape, a sawtooth wave shape, a sinusoidal shape, a circular shape, a stripe shape, a zigzag shape, and an omega (Ω) shape is repeatedly arranged, but embodiments of the present disclosure are not limited thereto.

Therefore, in order to minimize or at least reduce the stress concentrated on the plurality of link lines LL and the corresponding crack, the shape of the plurality of link lines LL may be formed in various shapes including the above-described shape, but embodiments of the present disclosure are not limited thereto.

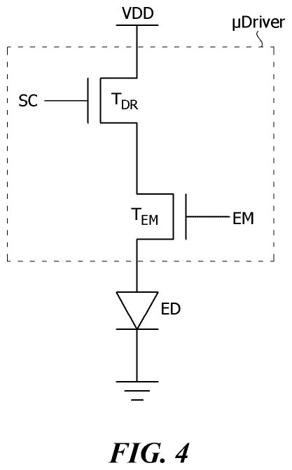

FIG. 4 is a diagram illustrating a circuit structure according to an embodiment of the present disclosure.

Although FIG. 4 illustrates that one light emitting element ED is connected to the micro-driver, the present disclosure is not limited thereto. For example, eight light emitting elements ED may be connected to one micro-driver. For another example, 16 light emitting elements ED may be connected to one micro-driver, 32 light emitting elements ED or 64 light emitting elements ED may be connected to one micro-driver at the same time. The light emitting element ED may be a micro-light emitting element μLED.

One micro driver μDriver may include a driving transistor TDR and a light emitting transistor TEM, but embodiments of the present disclosure are not limited thereto. For example, in the driving transistor TDR, a high potential power voltage VDD may be applied to the first electrode, a first electrode of the light emitting transistor TEM may be connected to the second electrode, and a scan signal SC may be applied to the gate electrode. The scan signal SC applied to the gate electrode of the driving transistor TDR may be a direct current power source, and a fixed reference voltage Vref may be applied to each frame or each sub-frame, but embodiments of the present disclosure are not limited thereto. Alternatively, depending on the type of the driving transistor, the first electrode thereof may be applied with a low-potential power supply.

In the light emitting transistor TEM, the second electrode of the driving transistor TDR may be connected to the first electrode, the light emitting element ED may be connected to the second electrode, and the light emitting signal EM may be applied to the gate electrode. The light emitting signal EM applied to the gate electrode of the light emitting transistor TEM may be a pulse width modulation signal that changes every frame, but embodiments of the present disclosure are not limited thereto. Alternatively, the emission signal EM applied to the gate electrode of the light-emitting transistor TEM may be a pulse width modulation signal that varies every sub-frame, and embodiments of the present disclosure are not limited thereto.

In the light emitting element ED, the first electrode may be connected to the second electrode of the light emitting transistor TEM, and the second electrode may be connected to the ground. For example, the first electrode may be an anode electrode and the second electrode may be a cathode electrode, but configurations of the present disclosure are not limited thereto. Alternatively, the first electrode may be a cathode electrode and the second electrode may be an anode electrode. Each of the driving transistor TDR and the light emitting transistor TEM may be an n-type transistor or a p-type transistor.

In the micro driver μDR, the driving transistor TDR may be turned on by the scan signal SC applied from the timing controller T-CON, and the light emitting transistor TEM may be turned on by the light emitting signal EM. As a result, the driving current may be applied to the light emitting element ED via the driving transistor TDR and the light emitting transistor TEM by the high potential power voltage VDD applied to the first electrode of the driving transistor TDR, and thus the light emitting element ED may emit light.

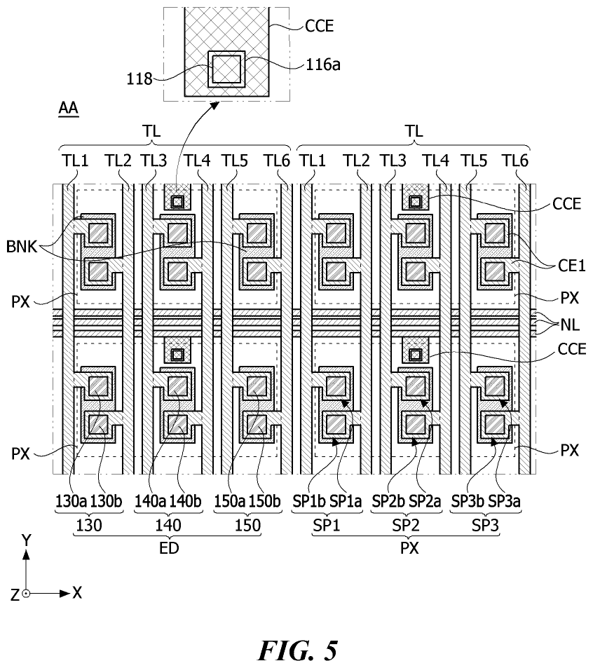

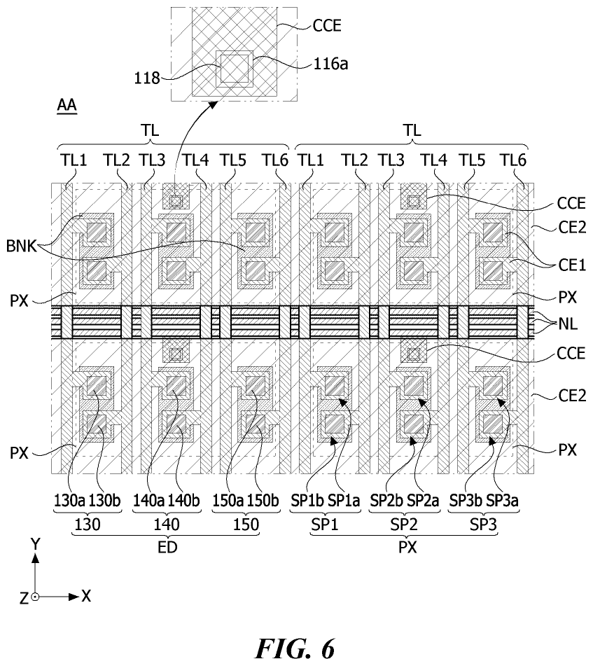

FIGS. 5 and 6 are plan views of a display device according to an embodiment of the present disclosure. For example, FIG. 5 is an enlarged plan view of a display area including a plurality of pixels. For example, FIG. 6 is an enlarged plan view of a display area including a plurality of pixels.

In FIG. 5, only a plurality of signal lines TL, a plurality of communication lines NL, a plurality of first electrodes CE1, a plurality of banks BNK, and a plurality of light emitting elements ED are illustrated, but embodiments of the present disclosure are not limited thereto. FIG. 6 is an enlarged plan view in which a plurality of second electrodes CE2 are additionally disposed in FIG. 5.

Referring to FIG. 5, a plurality of pixels PX including a plurality of sub-pixels may be disposed in the display area AA. Each of the plurality of sub-pixels may include a light emitting element ED and may independently emit light. The plurality of sub-pixels may form a plurality of rows and a plurality of columns and may be arranged in a matrix form, but configurations of the present disclosure are not limited thereto. Alternatively, the plurality of sub-pixels may be disposed in PenTile form, diamond form, diamond-like form, etc.

A plurality of sub-pixels may include a first sub-pixel SP1, a second sub-pixel SP2, and a third sub-pixel SP3. For example, any one of the first sub-pixel SP1, the second sub-pixel SP2, and the third sub-pixel SP3 may be a red sub-pixel, the other may be a green sub-pixel, and the rest may be a blue sub-pixel. Types of a plurality of sub-pixels are examples, and embodiments of the present disclosure are not limited thereto. For example, the plurality of sub-pixels may alternatively include a different number of sub-pixels emitting light of colors from a different color system such as CMYK.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may include a first-first sub-pixel SP1a and a first-second sub-pixel SP1b. The pair of second sub-pixels SP2 may include a second-first sub-pixel SP2a and a second-second sub-pixel SP2b.

The pair of third sub-pixels SP3 may include a third-first sub-pixel SP3a and a third-second sub-pixel SP3b. For example, one pixel PX may include a first-first sub-pixel SP1a, a first-second sub-pixel SP1b, a second-first sub-pixel SP2a, a second-second sub-pixel SP2b, a third-first sub-pixel SP3a, and a third-second sub-pixel SP3b, but embodiments of the present disclosure are not limited thereto.

A plurality of sub-pixels constituting one pixel PX may be variously arranged. For example, in one pixel PX, a pair of first sub-pixels SP1 may be disposed in the same column, a pair of second sub-pixels SP2 may be disposed in the same column, and a pair of third sub-pixels SP3 may be disposed in the same column. The first sub-pixel SP1, the second sub-pixel SP2, and the third sub-pixel SP3 may be disposed in the same row. The number and arrangement of a plurality of sub-pixels constituting one pixel PX are exemplary, and configurations of the present disclosure are not limited thereto. Alternatively, in the one pixel PX, a pair of first sub-pixels SP1 may be disposed in the same row, a pair of second sub-pixels SP2 may be disposed in the same row, and a pair of third sub-pixels SP3 may be disposed in the same row. The first sub-pixel SP1, the second sub-pixel SP2, and the third sub-pixel SP3 may be disposed in the same column.

A plurality of signal lines TL may be disposed in a region between the plurality of sub-pixels. The plurality of signal lines TL may extend in a column direction between the plurality of sub-pixels. The plurality of signal lines TL may be lines that transmit an anode voltage from the pixel driving circuit PD to a plurality of sub-pixels. For example, the plurality of signal lines TL may be electrically connected to the plurality of pixel driving circuits PD and the first electrode CE1 of the plurality of sub-pixels.

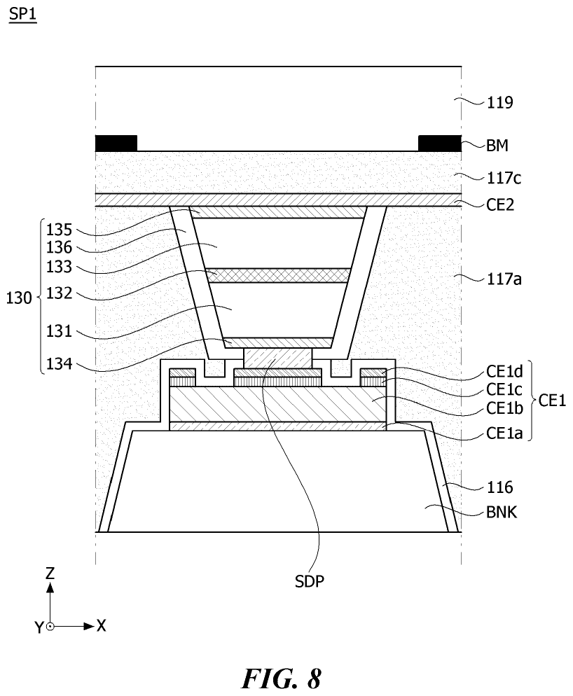

The anode voltage output from the pixel driving circuit PD may be transferred to the first electrodes CE1 of a plurality of sub-pixels through a plurality of signal lines TL. For example, the first electrode CE1 may be an electrode electrically connected to the anode electrode 134 (see FIG. 8) of the light emitting element ED. Accordingly, the anode voltage from the signal line TL may be transferred to the anode electrode 134 of the light emitting element ED through the first electrode CE1.

Accordingly, instead of forming a plurality of transistors and storage capacitors in each of the plurality of sub-pixels, the structure of the display device 1000 may be simplified by using the pixel driving circuit PD in which the plurality of pixel circuits are integrated. Also, as circuits disposed in each of the plurality of sub-pixels are integrated in one pixel driving circuit PD, high efficiency and low power driving may be possible.

A plurality of signal lines TL may for example include a first signal line TL1, a second signal line TL2, a third signal line TL3, a fourth signal line TL4, a fifth signal line TL5 and a sixth signal line TL6. For example, each of the first signal line TL1 and the second signal line TL2 may be electrically connected to each of a pair of first sub-pixels SP1, each of the third signal line TL3 and the fourth signal line TL4 may be electrically connected to each of a pair of second sub-pixels SP2, and each of the fifth signal line TL5 and the sixth signal line TL6 may be electrically connected to each of a pair of third sub-pixels SP3.

The first signal line TL1 may be positioned on one side of the pair of first sub-pixels SP1, and the second signal line TL2 may be positioned on the other side of the pair of first sub-pixels SP1. The first signal line TL1 may be electrically connected to the first electrode CE1 of one, e.g., the first-first sub-pixel SP1a of the pair of first sub-pixels SP1. The second signal line TL2 may be electrically connected to the first electrode CE1 of the other, e.g., the first-second sub-pixel SP1b, of the pair of first sub-pixels SP1.

The third signal line TL3 may be positioned on one side of the pair of second sub-pixels SP2, and the fourth signal line TL4 may be positioned on the other side of the pair of second sub-pixels SP2. For example, the third signal line TL3 may be positioned adjacent to the second signal line TL2. The third signal line TL3 may be electrically connected to the first electrode CE1 of one, e.g., the second-first sub-pixel SP2a, of the pair of second sub-pixels SP2. The fourth signal line TL4 may be electrically connected to the first electrode CE1 of the other, e.g., the second-second sub-pixel SP2b, of the pair of second sub-pixels SP2.

The fifth signal line TL5 may be positioned on one side of the pair of third sub-pixels SP3, and the sixth signal line TL6 may be positioned on the other side of the pair of third sub-pixels SP3. For example, the fifth signal line TL5 may be positioned adjacent to the fourth signal line TL4. The sixth signal line TL6 may be positioned adjacent to the first signal line TL1, which is connected to an adjacent pixel PX. The fifth signal line TL5 may be electrically connected to the first electrode CE1 of one, e.g., the third-first sub-pixel SP3a, of the pair of third sub-pixels SP3. The sixth signal line TL6 may be electrically connected to the first electrode CE1 of the other, e.g., the third-second sub-pixel SP3b, of the pair of third sub-pixels SP3.

The plurality of signal lines TL may be made of a conductive material. For example, the plurality of signal lines TL may be formed of a conductive material, such as titanium (Ti), silver (Ag), gold (Au), magnesium (Mg), aluminum (Al), copper (Cu), molybdenum (Mo), nickel (Ni), chromium (Cr), indium tin oxide (ITO), indium zinc oxide (IZO), indium gallium oxide (IGO), or indium gallium zinc oxide (IGZO), but the embodiments of the present disclosure are not limited thereto. In another example, the plurality of signal lines TL may have a multilayer structure of a conductive material. For example, the plurality of signal lines TL may have a multilayer structure of, e.g., titanium (Ti)/aluminum (Al)/titanium (Ti)/indium tin oxide (ITO), indium tin oxide (ITO)/aluminum (Al)/indium tin oxide (ITO), ITO/APC (AgPdCu)/ITO, but the embodiments of the present disclosure are not limited thereto.

The plurality of communication lines NL may be arranged in a region between the plurality of pixels PX. The plurality of communication lines NL may extend in a row direction in the region between the plurality of pixels PX. The plurality of communication lines NL may be arranged in a region between the plurality of second electrodes (CE2), and may not overlap the plurality of second electrodes CE2. For example, the plurality of communication lines NL may be lines used for short-range communication, such as near field communication (NFC), BlueTooth communication. The plurality of communication lines NL may function as an antenna. For example, the plurality of communication lines NL may be a plurality of connection lines or the like, but the embodiments of the present disclosure are not limited thereto.

According to the present disclosure, the bank BNK may be positioned in each of the plurality of sub-pixels. The plurality of banks BNK may be structures on which the plurality of light emitting element ED are mounted. The plurality of banks BNK may guide the positions of the plurality of light emitting element ED in a transfer process for transferring the plurality of light emitting element ED to the display device 1000. During the transfer process of the plurality of light emitting element ED, the plurality of light emitting element ED may be transferred onto the plurality of banks BNK. The plurality of banks BNK may be bank patterns or structures, but embodiments of present disclosure are not limited thereto.

Referring to FIGS. 5 and 6, the bank BNK of the first sub-pixel SP1, the bank BNK of the second sub-pixel SP2, and the bank BNK of the third sub-pixel SP3 may be spaced apart from each other. The bank BNK of the first sub-pixel SP1, the bank BNK of the second sub-pixel SP2, and the bank BNK of the third sub-pixel SP3 may be configured to be separated from each other. Accordingly, the bank BNK of the first sub-pixel SP1, the bank BNK of the second sub-pixel SP2, and the bank BNK of the third sub-pixel SP3, onto which different types of the light emitting element ED are transferred, may be easily distinguished.

The bank BNK of the first-first sub-pixel SP1a and the bank BNK of the first-second sub-pixel SP1b may be connected to each other or may be formed to be spaced apart from each other. For example, a first bank BNK of the first-first sub-pixel SP1a and a first bank BNK of the first-second sub-pixel SP1b on which the same type of light emitting element ED is disposed may be connected to each other or may be spaced apart from each other or separated from each other in consideration of a design such as a transfer process requirement and the like. In addition, a second bank BNK of the second-first sub-pixel SP2a and a second bank BNK of the second-second sub-pixel SP2b may be connected to each other or may be formed to be spaced apart from each other. In addition, a third bank BNK of the third-first sub-pixel SP3a and a third bank BNK of the third-second sub-pixel SP3b may be connected to each other or may be formed to be spaced apart from each other.

Accordingly, the first bank BNK of the pair of first sub-pixels SP1, the second bank BNK of the pair of second sub-pixels SP2, and the third bank BNK of the pair of third sub-pixels SP3 may be variously formed, and embodiments of the present disclosure are not limited thereto.

For example, the plurality of banks BNK may be formed of an organic insulating material. The plurality of banks BNK may be configured as a single layer or a multi-layer of the organic insulating material. For example, the plurality of banks BNK may be formed of a benzocyclobutene resin, a photosensitive polymer, a photoresist, polyimide (PI), or acryl-based material, but the embodiments of present disclosure are not limited thereto.

The first electrode CE1 may be positioned in each of the plurality of sub-pixels. For example, the first electrodes CE1 may be positioned on the banks BNK. The first electrode CE1 may be electrically connected to one of the plurality of signal lines TL.

At least a portion of the first electrode CE1 may extend outside of the banks BNK and be electrically connected to the signal line TL closest to the first electrode CE1. For example, a portion of the first electrode CE1 of the first-first sub-pixel SP1a may extend to one side area of the first-first sub-pixel SP1a and be electrically connected to the first signal line TL1, and a portion of the first electrode CE1 of the first-second sub-pixel SP1b may extend to the opposite side area of the first-second sub-pixel SP1b and be electrically connected to the second signal line TL2.

A portion of the first electrode CE1 of the second-first sub-pixel SP2a may extend to one side area of the second-first sub-pixel SP2a to be electrically connected to the third signal line TL3, and a portion of the first electrode CE1 of the second-second sub-pixel SP2b may extend to the other side area of the second-second sub-pixel SP2b to be electrically connected to the fourth signal line TL4. A portion of the first electrode CE1 of the third-first sub-pixel SP3a may extend to one side area of the third-first sub-pixel SP3a to be electrically connected to the fifth signal line TL5, and a portion of the first electrode CE1 of the third-second sub-pixel SP3b may extend to the other side area of the third-second sub-pixel SP3b to be electrically connected to the sixth signal line TL6. Embodiments of the present disclosure are not limited thereto.

The first electrode CE1 may be electrically connected to the anode electrode 134 (see FIG. 8) of the light emitting element ED, and may transmit the anode voltage from the pixel driving circuit PD to the light emitting element ED of each of the plurality of sub-pixels through the signal line TL. Different voltages may be applied to the respective first electrodes CE1 of the plurality of sub-pixels according to an image or video to be displayed. For example, different voltages may be applied to the respective first electrodes CE1 of the plurality of sub-pixels. Accordingly, the first electrode CE1 may be a pixel electrode, and the embodiments of the present disclosure are not limited thereto. Alternatively, the first electrode CE1 may be a common electrode, and the embodiments of the present disclosure are not limited thereto.

The first electrode CE1 may be formed of a conductive material. For example, the first electrode CE1 may be formed integrally with a plurality of signal lines TLs. For example, the first electrode CE1 may be formed of the same or substantially the same or different conductive material as a plurality of signal lines TLs, but embodiments of the present disclosure are not limited thereto. For example, the first electrode CE1 may be formed of a multi-layered structure of silver (Ag), gold (Au), magnesium (Mg), titanium (Ti), aluminum (Al), copper (Cu), molybdenum (Mo), nickel (Ni), chromium (Cr), indium tin oxide (ITO), indium zinc oxide (IZO), indium gallium oxide (IGO), indium gallium zinc oxide (IGZO), etc., but embodiments of the present disclosure are not limited thereto. For another example, the first electrode CE1 may be formed of a multi-layered structure of a conductive material. For example, a plurality of first electrodes CE1 may be formed of a multi-layered structure of, e.g., titanium (Ti)/aluminum (Al)/titanium (Ti)/indium tin oxide (ITO), indium tin oxide (ITO)/aluminum (Al)/indium tin oxide (ITO), ITO/APC (AgPdCu)/ITO, but embodiments of the present disclosure are not limited thereto.

A light emitting element ED may be disposed in each of a plurality of sub-pixels. A plurality of light emitting elements ED may be any one of a light-emitting diode (LED), a mini light-emitting diode (Mini LED) and a micro light-emitting diode (Micro LED), but embodiments of the present disclosure are not limited thereto. A plurality of light emitting elements ED may be disposed on the banks BNK and the first electrode CE1. A plurality of light emitting elements ED may be disposed on the first electrode CE1 and may be electrically connected to the first electrode CE1. Accordingly, the light emitting element ED may emit light by receiving the anode voltage from the pixel driving circuit PD through the signal line TL and the first electrode CE1.

The plurality of light emitting element ED may include a first light emitting element 130, a second light emitting element 140, and a third light emitting element ED 150. The first light emitting element ED 130 may be positioned in the first sub-pixel SP1. The second light emitting element ED 140 may be positioned in the second sub-pixel SP2. The third light emitting element ED 150 may be positioned in the third sub-pixel SP3. For example, one of the first light emitting element ED 130, the second light emitting element ED 140, and the third light emitting element ED 150 may be a red light emitting element ED, another one may be a green light emitting element ED, and the remaining one may be a blue light emitting element ED, but the embodiments of the present disclosure are not limited thereto. Accordingly, by combining red light, green light, and blue light emitted from the plurality of light emitting element EDs, various colors of light including white may be implemented. The numbers and types of the plurality of light emitting element ED are merely exemplary, and the embodiments of the present disclosure are not limited thereto. For example, the plurality of sub-pixels may alternatively include a different number of sub-pixels emitting light of colors from a different color system such as CMYK.

The first light emitting element 130 may include a first-first light emitting element 130a disposed in the first-first sub-pixel SP1a and a first-second light emitting element 130b disposed in the first-second sub-pixel SP1b. The second light emitting element 140 may include a second-first light emitting element 140a disposed in the second-first sub-pixel SP2a and a second-second light emitting element 140b disposed in the second-second sub-pixel SP2b. The third light emitting element 150 may include a third-first light emitting element 150a disposed in the third-first sub-pixel SP3a and a third-second light emitting element 150b disposed in the third-second sub-pixel SP3b.

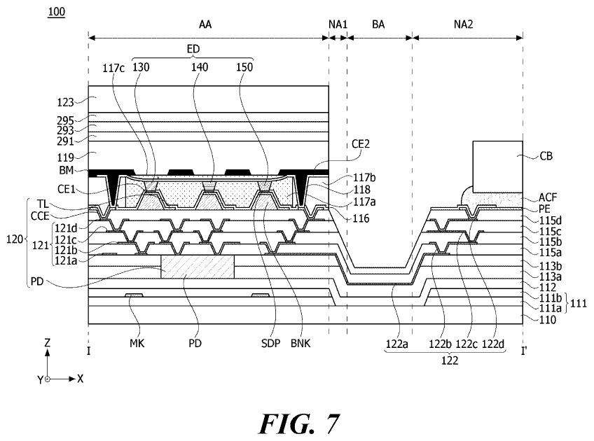

Referring to FIG. 6, the second electrode CE2 may be positioned in each of the plurality of sub-pixels. The second electrode CE2 may be positioned on the light emitting element ED. The second electrode CE2 may be electrically connected to the pixel driving circuit (PD of FIG. 7) through the plurality of contact electrodes CCE.

For example, the second electrode CE2 may be electrically connected to a cathode electrode (135 of FIG. 8) of the light emitting element ED and may transmit a cathode voltage from the pixel driving circuit PD to the light emitting element ED. The same cathode voltage may be applied to the second electrode CE2 of each of the plurality of sub-pixels. For example, the same voltage may be applied to the second electrode CE2 of each of the plurality of sub-pixels and the cathode electrode 135 of the light emitting element ED. Accordingly, the second electrode CE2 may be a common electrode, but the embodiments of the present disclosure are not limited thereto. Accordingly, the second electrode CE2 may be a pixel electrode, but the embodiments of the present disclosure are not limited thereto.

At least some of the plurality of sub-pixels may share the second electrode CE2. At least some of the second electrodes CE2 of the plurality of sub-pixels may be electrically connected to each other. As the same voltage is applied to the second electrodes CE2, the second electrodes CE2 of at least some sub-pixels may be shared. For example, the second electrodes CE2 of at least some of the plurality of pixels PX arranged in the same row may be connected to each other. For example, a single second electrode CE2 may be provided for the plurality of pixels PX. One second electrode CE2 may be provided for every n sub-pixels, wherein n is an integer larger than one.

For example, some of the second electrodes CE2 of the plurality of sub-pixels may be spaced apart or separated from each other. For example, the second electrode CE2 connected to the pixels PX in an n^{th} row and the second electrode CE2 connected to the pixels PX in an (n+1)th row may be spaced apart or separated from each other. For example, the plurality of second electrodes CE2 may be spaced apart from each other with the plurality of communication lines NL, which extend in the row direction, interposed or disposed therebetween.

The plurality of second electrodes CE2 may be made of a transparent conductive material, but the embodiments of the present disclosure are not limited thereto. The plurality of second electrodes CE2 may be made of a transparent conductive material, allowing light emitted from the micro-LED to be directed upward through the second electrode CE2. For example, the second electrode CE2 may be made of a transparent conductive material such as indium tin oxide (ITO), indium zinc oxide (IZO), indium gallium oxide (IGO), or indium gallium zinc oxide (IGZO), but the embodiments of the present disclosure are not limited thereto.

The plurality of contact electrodes CCE may be arranged on the substrate 110. For example, the plurality of contact electrodes CCE may be spaced apart from the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2 through contact holes 118 formed in the second optical layer 117b positioned to be spaced apart from the bank BNK.

The plurality of contact electrodes CCE may be positioned between the substrate 110 and the plurality of second electrodes CE2 and may transmit the cathode voltage from the pixel driving circuit PD to the second electrodes CE2.

FIG. 7 is a cross-sectional view of a display device according to an embodiment of the present disclosure. FIG. 8 is an enlarged cross-sectional view of a display device according to an embodiment of the present disclosure. For example, FIG. 7 is a cross-sectional view of the first and second non-display areas NA1 and NA2, and the bending area BA.

Referring to FIG. 7, a buffer layer 111 may be disposed in the remaining area of the substrate 110 except for the bending area BA. The buffer layer 111 may include a first buffer layer 111a and a second buffer layer 111b.

The first buffer layer 111a and the second buffer layer 111b may be positioned in the display area AA, the first non-display area NA1, and the second non-display area NA2. The first buffer layer 111a and the second buffer layer 111b may reduce the permeation of foreign matters such as moisture or impurities through the substrate 110. The first buffer layer 111a and the second buffer layer 111b may be made of an inorganic insulating material. For example, the first buffer layer 111a and the second buffer layer 111b may be configured as a single layer or multi-layer of silicon oxide (SiOₓ), silicon nitride (SiNₓ), or silicon oxynitride (SiOₓN_{y}), but the embodiments of the present disclosure are not limited thereto.

The non-display area NA may include a first non-display area NA1, a bending area BA, and a second non-display area NA2. The first and second buffer layers 111a and 111b may be disposed in the first and second non-display areas NA1 and NA2, and may be removed from the bending area BA. For example, the buffer layer 111 may be formed of a single layer or multiple layers of silicon oxide (SiOₓ), silicon nitride (SiNₓ) or silicon oxynitride (SiOₓN_{y}), which is an inorganic film material, but embodiments of the present disclosure are not limited thereto. For example, portions of the first buffer layer 111a and the second buffer layer 111b on the bending area BA may be removed. The upper surface of the substrate 110 located in the bending area BA may be exposed from the first buffer layer 111a and the second buffer layer 111b. By removing the first buffer layer 111a and the second buffer layer 111b made of the inorganic insulating material from the bending area BA, cracks in the first buffer layer 111a and the second buffer layer 111b that may occur during bending may be minimized or at least reduced.

A plurality of alignment keys MK may be arranged between the first buffer layer 111a and the second buffer layer 111b. The plurality of alignment keys MK may be configured to identify the position of the pixel driving circuit PD during the fabricating process of the display device 1000. For example, the plurality of alignment keys MK may be configured to align the position of the pixel driving circuit PD transferred onto an adhesive layer 112. In another example, the plurality of alignment keys MK may be omitted.

The adhesive layer 112 may be positioned on the second buffer layer 111b. The adhesive layer 112 may be positioned in the display area AA, the first non-display area NA1, the bending area BA, and the second non-display area NA2. In another example, at least a portion of the adhesive layer 112 may be removed from the non-display area NA that includes the bending area BA. For example, the adhesive layer 112 may be made of any one of an optically clear adhesive (OCA), an optically clear resin (OCR), a pressure sensitive adhesive (PSA), a silicone resin, an adhesive polymer, epoxy resin, UV-curable resin, a polyimide-based material, an acrylate-based material, a urethane-based material, or polydimethylsiloxane (PDMS), but the embodiments of the present disclosure are not limited thereto.

In the display area AA, the pixel driving circuit PD may be positioned on the adhesive layer 112. When the pixel driving circuit PD is implemented as a driving driver, the driving driver may be mounted on the adhesive layer 112 through a transfer process, but the embodiments of the present disclosure are not limited thereto.

A first protective layer 113a and a second protective layer 113b may be positioned on the upper or side surfaces of the adhesive layer 112 and the pixel driving circuit PD. The first protective layer 113a and the second protective layer 113b may be positioned to surround the side surface of the pixel driving circuit PD, but the embodiments of the present disclosure are not limited thereto. For example, the second protective layer 113b may be positioned to cover at least a portion of the upper surface of the pixel driving circuit PD. For example, at least one of the first protective layer 113a and the second protective layer 113b positioned in the bending area BA may be omitted.

For example, the first protective layer 113a may be entirely positioned over the display area AA and the non-display area NA, and the second protective layer 113b may be partially positioned over the display area AA, the first non-display area NA1, and the second non-display area NA2. For example, a portion of the second protective layer 113b in the bending area BA may be removed. However, the embodiments of the present disclosure are not limited thereto.

The first protective layer 113a and the second protective layer 113b may be formed of an organic insulating material, but the embodiments of the present disclosure are not limited thereto. For example, the first protective layer 113a and the second protective layer 113b may be formed of acrylic, phenolic, unsaturated polyester, polyamide, benzocyclobutene, polyphenylene, polyphenylene sulfide, photoresist, polyimide (PI), or a photoacryl-based material, but the embodiments of the present disclosure are not limited thereto. For example, the first protective layer 113a and the second protective layer 113b may be an overcoating layer or an insulating layer, but the embodiments of the present disclosure are not limited thereto.

A plurality of first connection lines 121 may be arranged on the second protective layer 113b in the display area AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a first-first connection line 121a, a first-second connection line 121b, a first-third connection line 121c, and a first-fourth connection line 121d, and the first-first connection line 121a, the first-second connection line 121b, the 1-3 connection line 121c, and the first-fourth connection line 121d may be electrically connected to each other through contact holes formed in insulating layers between the connection lines, but the embodiments of the present disclosure are not limited thereto.

For example, a plurality of first-first connection lines 121a may be disposed on the second protective layer 113b. A plurality of first-first connection lines 121a may be electrically connected to the pixel driving circuit PD. A plurality of first-first connection lines 121a may transfer voltages output from the pixel driving circuit PD to the first electrode CE1 or the second electrode CE2.

For example, the first and second protective layers 113a and 113b may be formed of an organic insulating material. For example, the first and second protective layers 113a and 113b may be formed of acrylic, phenolic, unsaturated polyester, polyamide, benzocyclobutene, polyphenylene, polyphenylene sulfide, a photo resist, polyimide (PI), a photoacryl-based material, or the like, but embodiments of the present disclosure are not limited thereto. For example, the first protective layer 113a and the second protective layer 113b may be formed of the same or different materials. Embodiments of the present disclosure are not limited thereto.

The first organic insulating layer 115a may be disposed on the second protective layer 113b. The inorganic insulating layer (not shown) may be disposed between the second protective layer 113b and the first organic insulating layer 115a but embodiments of the present disclosure are not limited thereto. The first organic insulating layer 115a may be formed of an organic insulating material, but embodiments of the present disclosure are not limited thereto. For example, the first organic insulating layer 115a may be formed of acrylic, phenolic, unsaturated polyester, polyamide, benzocyclobutene, polyphenylene, polyphenylene sulfide, a photo resist, polyimide (PI), a photoacryl-based material, or the like, but embodiments of the present disclosure are not limited thereto.

In addition, a plurality of first-second connection lines 121b may be disposed on the first organic insulating layer 115a. A plurality of first-second connection lines 121b may be indirectly connected to or directly connected to the pixel driving circuit PD. For example, a portion of the first-second connection line 121b may be directly connected to the pixel driving circuit PD through a contact hole of the first organic insulating layer 115a. Another portion of the first-second connection line 121b may be electrically connected to the first-first connection line 121a through a contact hole of the first organic insulating layer 115a. However, embodiments of the present disclosure are not limited thereto. The voltage output from the pixel driving circuit PD may be transferred to the first electrode CE1 or the second electrode CE2 through connection lines in addition to a plurality of first-second connection lines 121b.

A second organic insulating layer 115b may be positioned on the plurality of first-second connection lines 121b. The second organic insulating layer 115b may be entirely positioned over the display area AA and the non-display area NA, but the embodiments of the present disclosure are not limited thereto. Alternatively, the second organic insulating layer 115b may be partially positioned over the display area AA, the first non-display area NA1 and the second non-display area NA2. For example, a portion of the second organic insulating layer 115b positioned in the bending area BA may be removed. The second organic insulating layer 115b may be made of an organic insulating material, but the embodiments of the present disclosure are not limited thereto. For example, the first organic insulating layer 115a may be made of acrylic, phenolic, unsaturated polyester, polyamide, benzocyclobutene, polyphenylene, polyphenylene sulfide, photoresist, polyimide (PI), or a photoacryl-based material, but the embodiments of the present disclosure are not limited thereto.

The plurality of first-third connection lines 121c may be positioned on the second organic insulating layer 115b. The plurality of first-third connection lines 121c may be electrically connected to the plurality of first-second connection lines 121b. For example, the first-third connection line 121c may be electrically connected to the first-second connection line 121b through a contact hole of the second organic insulating layer 115b.

A third organic insulating layer 115c may be positioned on the plurality of first-third connection lines 121c. The third organic insulating layer 115c may be positioned in a region excluding the bending area BA, but the embodiments of the present disclosure are not limited thereto. The third organic insulating layer 115c may be positioned in the display area AA, the first non-display area NA1, and the second non-display area NA2, but the embodiments of the present disclosure are not limited thereto. For example, a portion of the third organic insulating layer 115c positioned in the bending area BA may be removed. The third organic insulating layer 115c may be made of an organic insulating material, but the embodiments of the present disclosure are not limited thereto. For example, the third organic insulating layer 115c may be made of acrylic, phenolic, unsaturated polyester, polyamide, benzocyclobutene, polyphenylene, polyphenylene sulfide, photoresist, polyimide (PI), or a photoacryl-based material, but the embodiments of the present disclosure are not limited thereto.

The plurality of first-fourth connection lines 121d may be positioned on the third organic insulating layer 115c. The plurality of first-fourth connection lines 121d may be electrically connected to the plurality of first-third connection lines 121c. For example, the first-fourth connection line 121d may be electrically connected to the first-third connection line 121c through a contact hole of the third organic insulating layer 115c.

A fourth organic insulating layer 115d may be disposed on a plurality of first-fourth connection lines 121d. The fourth organic insulating layer 115d may be disposed in the remaining area except for the bending area BA, but embodiments of the present disclosure are not limited thereto. The fourth organic insulating layer 115d may be disposed in the display area AA, the first non-display area NA1, and the second non-display area NA2, but embodiments of the present disclosure are not limited thereto.

According to the present disclosure, a plurality of second connection lines 122 may be positioned on the second protective layer 113b in the non-display area NA. The plurality of second connection lines 122 may be lines for transmitting a signal, which has been transmitted to the pad portion PAD from the flexible circuit board (or flexible film) CB and/or the printed circuit board 160 (see FIG. 1), to the pixel driving circuit PD of the display area AA. For example, the plurality of second connection lines 122 may be electrically connected to the plurality of pad electrodes PE to receive a signal from the flexible circuit board (or flexible film) CB and/or the printed circuit board 160.

For example, the plurality of second connection lines 122 may extend from the pad portion PAD toward the display area AA to transmit a signal to the line of the display area AA. In this case, the plurality of second connection lines 122 may function as the link lines LL. For example, the plurality of second connection lines 122 may include a second-first connection line 122a, a second-second connection line 122b, a second-third connection line 122c, and a second-fourth connection line 122d.

A plurality of second-first connection lines 122a may be disposed on the second protective layer 113b. A plurality of second-first connection lines 122a may extend from the second non-display area NA2 to the bending area BA and the first non-display area NA1. A plurality of second-first connection lines 122a may transmit signals transmitted from the flexible circuit board (or flexible film) CB and/or the printed circuit board to the pad unit PAD to the pixel driving circuit PD of the display area AA. For example, the plurality of second-first connection lines 122a may be electrically connected to the plurality of first-first connection lines 121a.

A plurality of second-second connection lines 122b may be disposed on the first organic insulating layer 115a. A plurality of second-second connection lines 122b may be disposed in the second non-display area NA2. The second-second connection line 122b may be electrically connected to the second-first connection line 122a through a contact hole of the first organic insulating layer 115a. Accordingly, the signal from the flexible circuit board (or flexible film) CB and/or the printed circuit board 160 may be transmitted to the second-first connection line 122a through the second-second connection line 122b.

A second-third connection line 122c may be disposed on the second organic insulating layer 115b. The second-third connection line 122c may be disposed in the second non-display area NA2. The second-third connection line 122c may be electrically connected to the second-second connection line 122b through a contact hole of the second organic insulating layer 115b. Accordingly, the signal from the flexible circuit board (or flexible film) CB and/or the printed circuit board may be transmitted to the second-first connection line 122a through the second-third connection line 122c and the second-second connection line 122b.

The third organic insulating layer 115c may be disposed on the second organic insulating layer 115b and the second-third connection line 122c. And, a second-fourth connection line 122d may be disposed on the third organic insulating layer 115c. The second-fourth connection line 122d may be disposed in the second non-display area NA2. The second-fourth connection line 122d may be electrically connected to the second-third connection line 122c through a contact hole of the third organic insulating layer 115c. Therefore, the signal from the flexible film CB and/or the printed circuit board may be transmitted to the second-first connection line 122a through the second-fourth connection line 122d, the second-third connection line 122c, and the second-second connection line 122b.

The plurality of first connection lines 121 and the plurality of second connection lines 122 may be formed of a highly flexible conductive material or any one of various conductive materials used in the display area AA.

For example, the second connection lines 122 in which a part is disposed in the bending area BA may be made of a conductive material having excellent ductility, such as gold (Au), Copper (Cu), silver (Ag), or aluminum (Al), but embodiments of the present disclosure are not limited thereto. For another example, the plurality of first connection lines 121 and the plurality of second connection lines 122 may be made of gold (Au), aluminum (Al), molybdenum (Mo), chromium (Cr), titanium (Ti), nickel (Ni), neodymium (Nd), copper (Cu), an alloy of silver (Ag) and magnesium (Mg), or other alloys thereof, but the embodiments of the present disclosure are not limited thereto.

The fourth organic insulating layer 115d may be positioned on the plurality of first connection lines 121 and the plurality of second connection lines 122. The fourth organic insulating layer 115d may be positioned in a region excluding the bending area BA, but the embodiments of the present disclosure are not limited thereto.

The fourth organic insulating layer 115d may be positioned in the display area AA, the first non-display area NA1, and the second non-display area NA2. A portion of the fourth organic insulating layer 115d in the bending area BA may be removed.

The fourth organic insulating layer 115d may be made of an organic insulating material, but the embodiments of the present disclosure are not limited thereto. For example, the fourth organic insulating layer 115d may be made of acrylic, phenolic, unsaturated polyester, polyamide, benzocyclobutene, polyphenylene, polyphenylene sulfide, photoresist, polyimide (PI), or a photoacryl-based material, but the embodiments of the present disclosure are not limited thereto.

In addition, the circuit layer 120 may include a pixel driving circuit PD, a plurality of connection lines 121 and 122, a signal line TL, and the like. The present disclosure is not limited thereto. A plurality of banks BNK may be disposed on the fourth organic insulating layer 115d in the display area AA. A plurality of banks BNK may be disposed to overlap each of a plurality of sub-pixels. One or more of the same type of light emitting devices ED may be disposed on each of a plurality of banks BNK.

A plurality of signal lines TL may be disposed on the fourth organic insulating layer 115d in the display area AA. A plurality of signal lines TL may be disposed in an area between a plurality of banks BNK. For example, a plurality of signal lines TL may be disposed adjacent to any one of a plurality of banks BNK.

A plurality of contact electrodes CCE may be disposed on the fourth organic insulating layer 115d in the display area AA. A plurality of contact electrodes CCE may supply a cathode voltage from the pixel driving circuit PD to the second electrode CE2. The first electrode CE1 may be disposed on the bank BNK. For example, the first electrode CE1 may be disposed to extend from the adjacent signal line TL toward the upper side of the bank BNK. The first electrode CE1 may be disposed on the upper surface of the bank BNK and the side surface of the bank BNK. For example, the first electrode CE1 may be disposed to extend from the signal line TL on the upper surface of the fourth organic insulating layer 115d to the side surface of the bank BNK and the upper surface of the bank BNK.

Referring to FIGS. 7 and 8, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto.

The first conductive layer CE1a may be positioned on the bank BNK. The second conductive layer CE1b may be positioned on the first conductive layer CE1a. The third conductive layer CE1c may be positioned on the second conductive layer CE1b. The fourth conductive layer CE1d may be positioned on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), an alloy of titanium (Ti) and indium tin oxide (ITO), or an alloy thereof, but the embodiments of the present disclosure are not limited thereto.

According to the present disclosure, among the plurality of conductive layers constituting the first electrode CE1, some conductive layers with high reflection efficiency may be configured as a reflector and/or an alignment key for aligning the light emitting element ED.

For example, among a plurality of conductive layers of the first electrode CE1, the second conductive layer CE1b may include a reflective material. For example, the second conductive layer CE1b may include aluminum (Al), but embodiments of the present disclosure are not limited thereto. Accordingly, the second conductive layer CE1b may be formed of a reflector. Also, due to the high reflection efficiency of the second conductive layer CE1b, identification may be easily performed in a manufacturing process, and accordingly, the position or transfer position of the light emitting device ED may be aligned based on the second conductive layer CE1b.

For example, in order to configure the second conductive layer CE1b as a reflector, the third conductive layer CE1c and the fourth conductive layer CE1d covering the second conductive layer CE1b may be partially removed or etched.

For example, portions of the third conductive layer CE1c and the fourth conductive layer CE1d positioned on the bank BNK may be removed or etched to expose the upper surface of the second conductive layer CE1b. For example, in the third conductive layer CE1c and the fourth conductive layer CE1d, a central portion where the solder pattern SDP is positioned and a border portion (or edge portion) may be left, while the remaining portions may be removed. For example, the border portion (or edge portion) of each of the third conductive layer CE1c formed of, e.g., titanium (Ti) and the fourth conductive layer CE1d formed of, e.g., indium tin oxide (ITO) may not be etched. Accordingly, it is possible to prevent or reduce another conductive layer of the first electrode CE1 from being corroded by a tetramethylammonium hydroxide (TMAH) solution used in the masking process of the first electrode CE1.

According to the present disclosure, the first conductive layer CE1a and the third conductive layer CE1c may be made of, e.g., titanium (Ti) or molybdenum (Mo). The second conductive layer CE1b may be made of, e.g., aluminum (Al), silver (Ag), gold (Au), magnesium (Mg), etc. The fourth conductive layer CE1d may include a transparent conductive oxide layer, such as indium tin oxide (ITO), indium gallium oxide (IGO), indium zinc oxide (IZO) or indium gallium zinc oxide (IGZO), which has good adhesion to the solder pattern SDP and exhibits corrosion resistance and acid resistance. However, the embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but embodiments of the present disclosure are not limited thereto.

According to the present disclosure, the signal line TL, the contact electrode CCE, and the pad electrode PE positioned in the same layer as the first electrode CE1 may be composed of multiple layers of a conductive material, but the embodiments of the present disclosure are not limited thereto. For example, the signal line TL, the contact electrode CCE, and the pad electrode PE may be formed of a multilayer of indium tin oxide (ITO)/titanium (Ti)/aluminum (Al)/titanium (Ti), indium tin oxide (ITO)/aluminum (Al)/indium tin oxide (ITO), ITO/APC/ITO, etc., but embodiments of the present disclosure are not limited thereto.

According to the present disclosure, the solder pattern SDP may be positioned on the first electrode CE1 in each of the plurality of sub-pixels. The solder pattern SDP may bond the micro-LED to the first electrode CE1 to electrically connect the first electrode CE1 to the micro-LED. For example, the first electrode CE1 and the anode electrode 134 of the micro-LED may be electrically connected to each other through eutectic bonding using the solder pattern SDP, but the embodiments of the present disclosure are not limited thereto. For example, when the solder pattern SDP be made of indium (In), and the anode electrode 134 of the micro-LED be made of gold (Au), the solder pattern SDP and the anode electrode 134 may be bonded by applying heat and pressure during the transfer process of the micro-LED. Through eutectic bonding, the micro-LED may be bonded to the solder pattern SDP and the first electrode CE1 without a separate adhesive material. For example, the solder pattern SDP may be made of indium (In), tin (Sn), or an alloy thereof, but the embodiments of the present disclosure are not limited thereto. For example, the solder pattern SDP may be a bonding pad or a joining pad, but the embodiments of the present disclosure are not limited thereto.

In addition, referring to FIG. 7, an insulating layer 116 may be disposed on the fourth organic insulating layer 115d including the first electrode CE1 and a bank BNK. For example, the insulating layer 116 may be disposed in the entire display area AA and the non-display area NA.

For example, the insulating layer 116 may be formed of a single layer or multiple layers of silicon oxide (SiOₓ), silicon nitride (SiNₓ) or silicon oxynitride (SiOₓN_{y}), which is an inorganic film material, but embodiments of the present disclosure are not limited thereto.

According to the present disclosure, the insulating layer 116 serving as the passivation layer may be disposed on a plurality of signal lines TL, a plurality of first electrodes CE1, a plurality of contact electrodes CCE, and a fourth organic insulating layer 115d. For example, the insulating layer 116 may be positioned in the display area AA, the first non-display area NA1, and the second non-display area NA2. A portion of the insulating layer 116 positioned in the bending area BA may be removed. In the second non-display area NA2, a portion of the insulating layer 116 covering the plurality of pad electrodes PE may be removed. Since the insulating layer 116 is positioned to cover the remaining regions other than the bending area BA and the regions where the plurality of pad electrodes PE and the solder pattern SDP are positioned, penetration of foreign matters such as moisture or impurities into the light emitting element ED may be reduced. For example, the insulating layer 116 may be composed of a single layer or multiple layers of silicon oxide (SiOₓ), silicon nitride (SiNₓ) or silicon oxynitride (SiOₓN_{y}), but the embodiments of the present disclosure are not limited thereto.

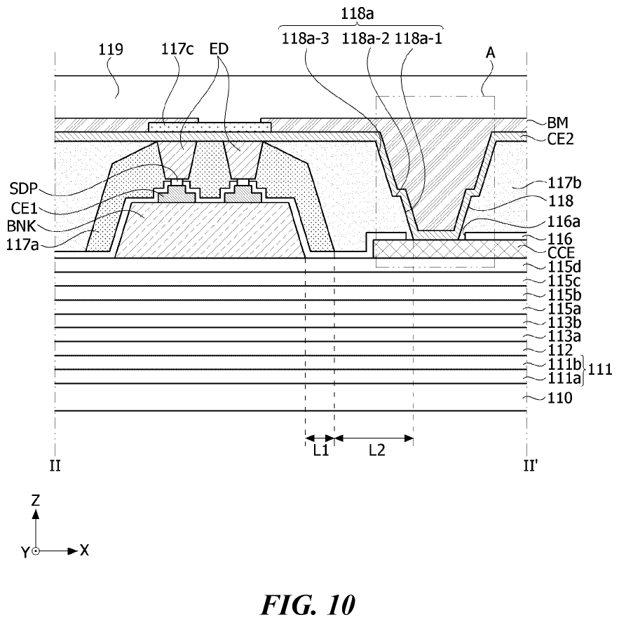

In addition, the insulating layer 116 may include a hole exposing the solder pattern SDP. The insulating layer 116 may also include an opening (116a of FIG. 10) exposing an upper part of the contact electrode CCE to a part positioned on the contact electrode CCE.

In each of the plurality of sub-pixels, the light-emitting element ED may be positioned on the solder pattern SDP. For example, the first light-emitting element 130 may be positioned in the first sub-pixel SP1, the second light-emitting element 140 may be positioned in the second sub-pixel SP2, and the third light-emitting element 150 may be positioned in the third sub-pixel SP3.

The light-emitting element ED may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), Laser assisted Deposition (LCVD), atomic layer deposition (ALD), thermal evaporation or sputtering, but the embodiments of the present disclosure are not limited thereto.

Referring to FIGS. 7 and 8, the first light-emitting element 130 may include the anode electrode 134, a first semiconductor layer 131, an active layer 132, a second semiconductor layer 133, the cathode electrode 135, and an encapsulation film 136, but the embodiments of the present disclosure are not limited thereto. For example, the first light-emitting element 130 may not include the encapsulation film 136. A first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a compound semiconductor of a group III-V, a group II-VI or the like and may be doped with an impurity (or dopant). For example, one of the first semiconductor layer 131 and the second semiconductor layer 133 may be a semiconductor layer doped with an n-type impurity, while the other may be a semiconductor layer doped with a p-type impurity, but the embodiments of the present disclosure are not limited thereto. For example, at least one of the first semiconductor layer 131 and the second semiconductor layer 133 may be a layer in which an n-type or p-type impurity is doped into a material such as gallium nitride (GaN), gallium phosphide (GaP), gallium arsenide phosphide (GaAsP), indium gallium nitride (InGaN), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium nitride (AlGaN), aluminum gallium arsenide (AlGaAs), or gallium arsenide (GaAs), but the embodiments of the present disclosure are not limited thereto.

For example, the n-type impurity may be phosphide (P), antimony (Sb), arsenide (As), silicon (Si), germanium (Ge), selenium (Se), carbon (C), tellurium (Te), tin (Sn), or the like, but embodiments of the present disclosure are not limited thereto. For example, the p-type impurity may be boron (B), aluminum (Al), gallium (Ga), magnesium (Mg), zinc (Zn), calcium (Ca), strontium (ST), barium (Ba), beryllium (Be), or the like, but embodiments of the present disclosure are not limited thereto.

For example, each of the first semiconductor layer 131 and the second semiconductor layer 133 may be a nitride semiconductor including an n-type impurity and a nitride semiconductor including a p-type impurity, but embodiments of the present disclosure are not limited thereto. For example, the first semiconductor layer 131 may be a nitride semiconductor including a p-type impurity, and the second semiconductor layer 133 may be a nitride semiconductor including an n-type impurity, but embodiments of the present disclosure are not limited thereto.

The active layer 132 may be positioned between the first semiconductor layer 131 and the second semiconductor layer 133. The active layer 132 may emit light by receiving holes and electrons from the first semiconductor layer 131 and the second semiconductor layer 133. For example, the active layer 132 may be configured in one of a single well structure, a multi-well structure, a single quantum well structure, a multi-quantum well (MQW) structure, a quantum dot structure, and a quantum line structure, but the embodiments of the present disclosure are not limited thereto. For example, the active layer 132 may be made of indium phosphide (InP), gallium arsenide (GaAs), aluminum gallium arsenide (AlGaAs), indium gallium nitride (InGaN) or gallium nitride (GaN), but the embodiments of the present disclosure are not limited thereto.

For another example, the active layer 132 may include a well layer and a multi-quantum well (MQW) structure having a barrier layer having a band gap higher than that of the well layer. For example, the active layer 132 may include, e.g., InGaN as a well layer and, e.g., AlGaN layer as a barrier layer, but embodiments of the present disclosure are not limited thereto.

The anode electrode 134 may be disposed between the first semiconductor layer 131 and the solder pattern SDP. For example, the anode electrode 134 may electrically connect the first semiconductor layer 131 to the first electrode CE1. The anode voltage output from the pixel driving circuit PD may be applied to the first semiconductor layer 131 through the signal line TL, the first electrode CE1, and the anode electrode 134. For example, the anode electrode 134 may be formed of a conductive material capable of eutectic bonding with the solder pattern SDP. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the embodiments of the present disclosure are not limited thereto.

The cathode electrode 135 may be positioned on the second semiconductor layer 133. For example, the cathode electrode 135 may electrically connect the second semiconductor layer 133 to the second electrode CE2. The cathode voltage outputted from the pixel driving circuit PD may be applied to the second semiconductor layer 133 through the contact electrode CCE, the second electrode CE2, and the cathode electrode 135. The cathode electrode 135 may be formed of a transparent conductive material such that light emitted from the micro-LED may be directed toward an upper side of the micro-LED, but the embodiments of the present disclosure are not limited thereto. For example, the cathode electrode 135 may be formed of a material such as indium tin oxide (ITO), indium zinc oxide (IZO), indium gallium oxide (IGO), or indium gallium zinc oxide (IGZO), but the embodiments of the present disclosure are not limited thereto.

The encapsulation film 136 may be positioned on at least portions of the first semiconductor layer 131, the active layer 132, the second semiconductor layer 133, the anode electrode 134, and the cathode electrode 135. For example, the encapsulation film 136 may surround at least portions of the first semiconductor layer 131, the active layer 132, the second semiconductor layer 133, the anode electrode 134, and the cathode electrode 135.

For example, the encapsulation film 136 may be disposed on at least a portion of the anode electrode 134 and the cathode electrode 135, for example, on the edge portion (or edge portion or one side) of the anode electrode 134 and the edge portion (or edge portion or one side) of the cathode electrode 135. At least a portion of the anode electrode 134 may be exposed from the encapsulation layer 136 to connect the anode electrode 134 and the solder pattern SDP. For example, at least a portion of the cathode electrode 135 may be exposed from the encapsulation layer 136 to connect the cathode electrode 135 and the second electrode CE2. For example, the encapsulation layer 136 may be formed of an insulating material such as silicon nitride (SiNₓ), silicon oxide (SiOₓ) or silicon oxynitride (SiOₓN_{y}), but embodiments of the present disclosure are not limited thereto.

As another example, the encapsulation layer 136 may have a structure in which a reflective material is dispersed in a resin layer, but embodiments of the present disclosure are not limited thereto. For example, the encapsulation layer 136 may be manufactured as a reflector having various structures, but embodiments of the present disclosure are not limited thereto. Light emitted from the active layer 132 by the encapsulation layer 136 may be reflected upward to improve light extraction efficiency. For example, the encapsulation layer 136 may be a reflective layer, but embodiments of the present disclosure are not limited thereto.

Although the light emitting element ED has been described as a vertical type structure according to the present disclosure, embodiments of the present disclosure are not limited thereto. For example, the light emitting element ED may have a lateral structure or a flip chip structure.

Although the first light emitting element 130 has been described with reference to FIG. 8, the second light emitting element 140 and the third light emitting element 150 may have substantially the same structure as the first light emitting element 130. For example, the second light emitting element 140 and the third light emitting element 150 may include substantially the same components as the first semiconductor layer 131, the active layer 132, the second semiconductor layer 133, the anode electrode 134, the cathode electrode 135, and the encapsulation film 136.

According to the present disclosure, a first optical layer 117a may be positioned on the insulating layer 116 to surround the plurality of light emitting element ED in the display area AA. For example, the first optical layer 117a may be positioned to cover the plurality of light emitting element ED and the bank BNK in regions of the plurality of sub-pixels. For example, the first optical layer 117a may cover the bank BNK, a portion of the passivation layer 116 and the spaces between the plurality of light emitting element ED. The first optical layer 117a may be positioned between the plurality of banks BNK and between the plurality of light emitting element ED included in one pixel PX, or may cover those spaces. For example, the first optical layer 117a may extend in a first direction X and may be separated in a second direction Y. For example, the first optical layer 117a may be positioned between the passivation layer 116 and the second electrode CE2 to surround the side portions of the light emitting element ED and the bank BNK, but the embodiments of the present disclosure are not limited thereto.

For example, the first optical layer 117a may be a diffusion layer, a sidewall diffusion layer, or the like, but the embodiments of the present disclosure are not limited thereto. The first optical layer 117a may be formed of an organic insulating material in which fine particles are dispersed, but the embodiments of the present disclosure are not limited thereto. For example, the first optical layer 117a may be made of siloxane in which fine metal particles such as titanium dioxide (TiO₂) particles are dispersed, but the embodiments of the present disclosure are not limited thereto. Light from the plurality of light emitting element ED may be scattered by the fine particles dispersed in the first optical layer 117a and emitted to the outside of the display device 1000. Accordingly, the first optical layer 117a may improve the light extraction efficiency of the light emitted from the plurality of light emitting element ED.

For example, the first optical layer 117a may be positioned in each of the plurality of pixels PX, or may be commonly positioned in some of the pixels PX arranged in the same row, but the embodiments of the present disclosure are not limited thereto. For example, the first optical layer 117a may be positioned in each of the plurality of pixels PX, or a single first optical layer 117a may be shared by the plurality of pixels PX. In another example, each of the plurality of sub-pixels may separately include the first optical layer 117a, but the embodiments of the present disclosure are not limited thereto.

According to the present disclosure, the second optical layer 117b may be disposed on the insulating layer 116 in the display area AA. For example, the second optical layer 117b may be disposed to surround the first optical layer 117a. For example, the second optical layer 117b may be in contact with the side surface of the first optical layer 117a. For example, the second optical layer 117b may be disposed in an area between a plurality of pixels PX. However, embodiments of the present disclosure are not limited thereto, for example, the second optical layer 117b may be a diffusion layer, a diffusion layer window, a window diffusion layer, or the like, but embodiments of the present disclosure are not limited thereto.

The second optical layer 117b may be formed of an organic insulating material, but embodiments of the present disclosure are not limited thereto. The second optical layer 117b may be formed of the same or different material as/from the first optical layer 117a, but embodiments of the present disclosure are not limited thereto. For example, the first optical layer 117a may include fine particles, and the second optical layer 117b may not include fine particles. For example, the second optical layer 117b may be formed of siloxane, but embodiments of the present disclosure are not limited thereto.

For example, the thickness of the first optical layer 117a may be less than that of the second optical layer 117b, but embodiments of the present disclosure are not limited thereto. Accordingly, when viewed in a plan view, the region in which the first optical layer 117a is disposed may include a concave portion recessed inwardly from the upper surface of the second optical layer 117b.

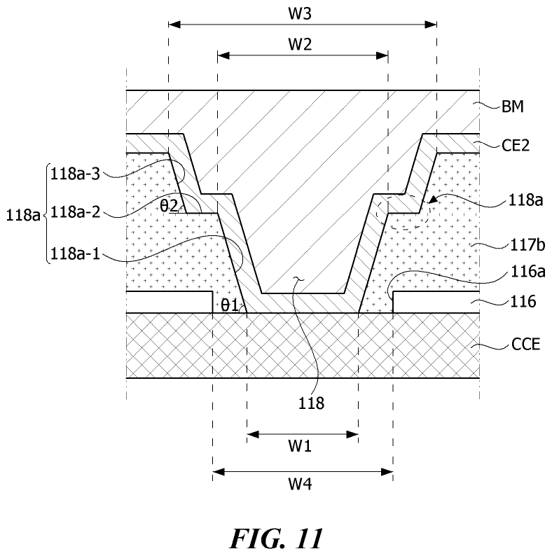

According to the present disclosure, the second electrode CE2 may be disposed on the first optical layer 117a and the second optical layer 117b. For example, the second electrode CE2 may be electrically connected to a plurality of contact electrodes CCE through a contact hole (118 of FIG. 11) of the second optical layer 117b positioned on the contact electrodes CCE. For example, the second electrode CE2 may be disposed on a plurality of light emitting elements ED. For example, the second electrode CE2 may include a transparent conductive oxide such as indium tin oxide (ITO), indium zinc oxide (IZO), indium gallium oxide (IGO) or indium gallium zinc oxide (IGZO), but embodiments of the present disclosure are not limited thereto. For example, the second electrode CE2 may be disposed to be in contact with the cathode electrode 135. For example, the second electrode CE2 may overlap the first optical layer 117a. For example, the flat outer surface of the first optical layer 117a may be covered. The second electrode CE2 may continuously extend in the first direction X of the substrate 110.

Accordingly, the second electrode CE2 may be commonly connected to a plurality of pixels PX arranged in the first direction X. For example, the second electrode CE2 may be commonly connected to a plurality of pixels PX. Further, in some embodiments, the second electrode CE2 is in planar contact with at least one light-emitting element ED among a first light-emitting element positioned on the left side and a second light-emitting element on the right side, as illustrated in FIG. 10.

According to the present disclosure, the second electrode CE2 may continuously extend on the first optical layer 117a, the second optical layer 117b, and the light emitting element ED. The region in which the first optical layer 117a is disposed may include a concave portion recessed inwardly from the upper surface of the second optical layer 117b. Accordingly, since the first portion of the second electrode CE2 disposed on the first optical layer 117a is disposed along the concave portion, the first portion may be disposed at a lower position than the second portion of the second electrode CE2 disposed on the second optical layer 117b.

In addition, the third optical layer 117c may be disposed on the second electrode CE2. The third optical layer 117c may be disposed to overlap a plurality of light emitting elements ED and the first optical layer 117a. Since the third optical layer 117c is disposed on the second electrode CE2 and a plurality of light emitting elements ED, a stain (Mura) that may occur in some of a plurality of light emitting elements ED may be improved. For example, when a plurality of light emitting elements ED are transferred onto the substrate 110 of the display device 1000, a region in which a gap between a plurality of light emitting elements ED is not uniform due to a process variation or the like may occur. When the spacing between the plurality of light emitting elements ED is non-uniform, the light emitting area of each of the plurality of light emitting elements ED may be non-uniformly disposed, and thus a stain (Mura) may be visually recognized by the user.

Accordingly, since the third optical layer 117c configured to uniformly diffuse light on the plurality of light emitting elements ED is configured, light emitted from some light emitting elements ED may be reduced or prevented from being visually recognized like a stain.

Therefore, since the light emitted from the plurality of light emitting elements ED is evenly diffused by the third optical layer 117c and extracted to the outside of the display device 1000, the luminance uniformity of the display device 1000 may be improved.

The third optical layer 117c may be formed of an organic insulating material in which fine particles are dispersed, but embodiments of the present disclosure are not limited thereto. For example, the third optical layer 117c may be formed of siloxane in which fine metal particles such as titanium dioxide (TiO₂) particles are dispersed, but embodiments of the present disclosure are not limited thereto. For example, the third optical layer 117c may be formed of the same material as the first optical layer 117a, but embodiments of the present disclosure are not limited thereto. For example, the third optical layer 117c may be a diffusion layer, an upper diffusion layer, or the like, but embodiments of the present disclosure are not limited thereto.

According to the present disclosure, light from a plurality of light emitting elements ED may be scattered by fine particles dispersed in the third optical layer 117c and emitted to the outside of the display device 1000. The third optical layer 117c may evenly mix light emitted from a plurality of light emitting elements ED to further improve luminance uniformity of the display device 1000.

In addition, light extraction efficiency of the display device 1000 may be improved by light scattered from a plurality of fine particles, and thus the display device 1000 may be driven at a low power.

In the display area AA, a black matrix BM may be disposed on the second electrode CE2, the first optical layer 117a, the second optical layer 117b and the third optical layer 117c. For example, the black matrix BM may fill a contact hole of the second optical layer 117b-1. Since the black matrix BM is configured to cover the display area AA, color mixture and reflection of external light of a plurality of sub-pixels may be reduced. For example, since the black matrix BM is disposed within a contact hole 117b-1 in which the second electrode CE2 is connected with the contact electrode CCE, light leakage between a plurality of neighboring sub-pixels may be prevented or reduced.

For example, the black matrix BM may be formed of an opaque material, but embodiments of the present disclosure are not limited thereto. For example, the black matrix BM may be an organic insulating material to which a black pigment or a black dye such as carbon black, Kochen black, nigrosine is added, but embodiments of the present disclosure are not limited thereto.

In some embodiments, the third optical layer 117c overlaps both light-emitting elements ED (e.g., a first light-emitting element positioned on the left side and a second light-emitting element on the right side, as illustrated in FIG. 10) when viewed in plan view. Additionally, a lateral dimension (LTD1) of the third optical layer 117c is smaller than a lateral dimension (LTD2) of the bank BNK. As illustrated in FIG. 10, the bank BNK has a trapezoidal cross-sectional shape, and the smallest lateral dimension of the bank BNK is greater than the lateral dimension LTD1 of the third optical layer 117c.

In the display area AA, a cover layer 119 may be disposed on the black matrix BM. The cover layer 119 may protect an element under the cover layer 119, for example, the cover layer 119 may be formed of an organic insulating material, but embodiments of the present disclosure are not limited thereto. For example, the cover layer 119 may be formed of acrylic, phenolic, unsaturated polyester, polyamide, benzocyclobutene, polyphenylene, polyphenylene sulfide, a photo resist, polyimide (PI), a photo acryl-based material, or the like, but embodiments of the present disclosure are not limited thereto. For example, the cover layer 119 may be an overcoating layer, an insulating layer, or the like, but embodiments of the present disclosure are not limited thereto.

As shown in FIG. 1, the polarizing layer 293 may be disposed on the cover layer 119 via the first adhesive layer 291. The cover member 123 may be disposed on the polarizing layer 293 via the second adhesive layer 295. For example, the first adhesive layer 291 and the second adhesive layer 295 may include an optically clear adhesive (OCA), an optically clear resin (OCR), a pressure sensitive adhesive (PSA), an adhesive polymer, epoxy resin, UV-curable resin, a polyimide-based material, an acrylate-based material, a urethane-based material, or polydimethylsiloxane (PDMS), or the like, but embodiments of the present disclosure are not limited thereto.

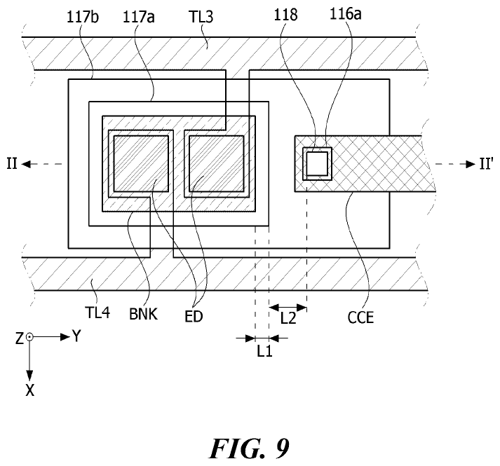

FIG. 9 is an enlarged plan view of a part of a display device according to an embodiment of the present disclosure. FIG. 10 is a cross-sectional view along line II-II′ of FIG. 9 and is a cross-sectional view of a display device according to an embodiment of the present disclosure. FIG. 11 is an enlarged cross-sectional view of portion A in FIG. 10.

Referring to FIGS. 9 and 10, in a display device according to the embodiment of the present disclosure, a plurality of banks BNK may be disposed on a substrate, and a plurality of light-emitting elements ED may be disposed on the plurality of banks BNK.

Here, a first electrode CE1 may be disposed between the plurality of banks BNK and the plurality of light-emitting elements ED. The first electrode CE1 may be formed of a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto.

For example, each of the first conductive layer CE1a, the second conductive layer CE1b, the third conductive layer CE1c, and the fourth conductive layer CE1d may be formed of titanium (Ti), molybdenum (Mo), aluminum (Al), an alloy of titanium (Ti) and indium tin oxide (ITO), or an alloy thereof, but the embodiments of the present disclosure are not limited thereto.

In addition, some of the plurality of conductive layers constituting the first electrode CE1, which have good reflection efficiency, may be formed as an alignment key for aligning the light-emitting element ED and/or a reflector. For example, the second conductive layer CE1b among the plurality of conductive layers of the first electrode CE1 may include a reflective material. For example, the second conductive layer CE1b may include aluminum (Al), silver (Ag), gold (Au), magnesium (Mg), but the embodiments of the present disclosure are not limited thereto. Accordingly, the second conductive layer CE1b may be formed to be a reflector. In addition, due to the high reflection efficiency of the second conductive layer CE1b, the second conductive layer CE1b can be easily identified during the manufacturing process, and thus the location or transfer location of the light-emitting element ED may be aligned based on the second conductive layer CE1b.

For example, to form the second conductive layer CE1b to be a reflector, parts of the third conductive layer CE1c and the fourth conductive layer CE1d that cover the second conductive layer CE1b may be removed or etched to expose an upper surface the second conductive layer CE1b. For example, central portions, in which a solder pattern SDP is disposed, and edge portions of the third conductive layer CE1c and the fourth conductive layer CE1d may remain, and the remaining portions not including the central and edge portions may be removed. In addition, the edge portion of each of the third conductive layer CE1c formed of, e.g., titanium (Ti) and the fourth conductive layer CE1d formed of, e.g., indium tin oxide (ITO) may not be etched. Accordingly, it is possible to prevent or reduce other conductive layers of the first electrode CE1 from being corroded by a tetramethylammonium hydroxide (TMAH) solution used in a masking process of the first electrode CE1.

In addition, the first conductive layer CE1a and the third conductive layer CE1c may include, e.g., titanium (Ti) or molybdenum (Mo). The second conductive layer CE1b may include, e.g., aluminum (Al), silver (Ag), gold (Au), magnesium (Mg), etc. The fourth conductive layer CE1d may include a transparent conductive oxide layer, such as indium tin oxide (ITO), indium gallium oxide (IGO), indium zinc oxide (IZO) or indium gallium zinc oxide (IGZO), which has high adhesion to the solder pattern SDP, corrosion resistance, and acid resistance. The embodiments of the present disclosure are not limited thereto.

In addition, a signal line TL, a contact electrode CCE, and a pad electrode that are disposed on the same layer as the first electrode CE1 may be formed of multiple layers of conductive materials. The embodiments of the present disclosure are not limited thereto.

The solder pattern SDP may be disposed on the first electrode CE1 disposed below the light-emitting element ED. The solder pattern SDP may bond the light-emitting element ED to the first electrode CE1. The first electrode CE1 and the light-emitting element ED may be electrically connected through eutectic bonding using the solder pattern SDP, but the embodiments of the present disclosure are not limited thereto.

In addition, the contact electrode CCE formed on the same layer as the first electrode CE1 may be disposed on a substrate 110 spaced a predetermined distance from the bank BNK. The first electrode CE1 may extend to an upper surface and side surfaces of the bank BNK and may be connected to a pixel driving circuit PD (see FIG. 7) and a pad PE.

The contact electrode CCE formed on the same layer as the first electrode CE1 may be formed of a plurality of conductive layers. For example, the contact electrode CCE may include a first contact conductive layer, a second contact conductive layer, a third contact conductive layer, and a transparent conductive layer, but the embodiments of the present disclosure are not limited thereto.

For example, each of the first contact conductive layer, the second contact conductive layer, the third contact conductive layer, and the transparent conductive layer may be formed of titanium (Ti), molybdenum (Mo), aluminum (Al), an alloy of titanium (Ti) and indium tin oxide (ITO), or an alloy thereof, but the embodiments of the present disclosure are not limited thereto.

The transparent conductive layer applied as an uppermost layer of the contact electrode CCE may include a transparent conductive oxide layer, such as an indium tin oxide (ITO) or indium zinc oxide (IZO) layer, that is corrosion-resistant and acid-resistant. The embodiments of the present disclosure are not limited thereto. To electrically connect the contact electrode CCE to a second electrode CE2, the contact electrode CCE and the second electrode CE2 may be electrically connected through a contact hole 118 formed in a second optical layer 117b disposed on the contact electrode CCE.

However, the uppermost layer of the contact electrode CCE disposed in the second optical layer 117b may be formed of ITO, which is a transparent conductive layer. Due to low adhesion at an interface between the second optical layer 117b and the transparent conductive layer, which is the uppermost layer of the contact electrode CCE, a delamination phenomenon may occur.

Accordingly, to prevent such a delamination phenomenon, a part of the ITO, which is a transparent conductive layer of the contact electrode CCE disposed in an area of the contact hole 118, may be removed.

In addition, referring to FIG. 10, an insulating layer 116 may be disposed on the plurality of banks BNK, the first electrode CE1, and the contact electrode CCE. Specifically, the insulating layer 116 that serves as a passivation layer may be disposed on a plurality of signal lines TL, a plurality of first electrodes CE1, a plurality of contact electrodes CCE, and a fourth organic insulating layer 115d. For example, the insulating layer 116 may be disposed on a display area AA, a first non-display area NA1, and a second non-display area NA2. A part of the insulating layer 116 disposed in a bending area BA may be removed. A part of the insulating layer 116 covering the plurality of pad electrodes PE in the second non-display area NA2 may be removed. Since the insulating layer 116 is disposed to cover the remaining areas not including the bending area BA and the areas in which the plurality of pads PE and the solder pattern SDP are disposed, it is possible to reduce the penetration of foreign matters such as moisture or impurities into the light-emitting element ED. For example, the insulating layer 116 may be formed of a single layer or multiple layers of silicon oxide (SiOₓ), silicon nitride (SiNₓ) or silicon oxynitride (SiOₓN_{y}) that is an inorganic film material, but the embodiments of the present disclosure are not limited thereto. For example, the insulating layer 116 may be a protective layer, a passivation layer, etc., but the embodiments of the present disclosure are not limited thereto.

In addition, referring to FIGS. 10 and 11, the contact hole 118 has a tapered or sloped profile. For example, the contact hole 118 has a lateral dimension that increases in a direction toward the second electrode CE2 or the cover layer 119 (e.g., direction opposite of the substrate 110). That is, a lateral dimension W3 is greater than W2 and W2 is greater than W1. Further, the contact hole 118 may overlap a region of the circuit layer 120 that is free of the bank BNK.

In some embodiments, the insulating layer 116 disposed on the contact electrode CCE may have an opening 116a. A width W4 of the opening 116a may be greater than a width W1 of a lower side of the contact hole 118 formed in the second optical layer 117b. The contact hole 118 may electrically connect the second electrode CE2 to the contact electrode CCE. The insulating layer 116 may form the opening 116a, thereby securing a formation margin of the contact hole 118. Accordingly, it is possible to improve misalignment of the contact hole 118.

The first optical layer 117a may be disposed on the insulating layer 116 covering the plurality of light-emitting elements ED on the bank BNK. For example, the first optical layer 117a may be disposed to cover the plurality of light-emitting elements ED and the bank BNK. For example, the first optical layer 117a may cover spaces between the bank BNK, a part of the insulating layer 116, and the plurality of light-emitting elements ED. The first optical layer 117a may be disposed between the plurality of light-emitting elements ED and between the plurality of banks BNK, which are included in one pixel PX, or may cover the plurality of light-emitting elements ED and the plurality of banks BNK. For example, the first optical layer 117a may be disposed to surround side portions of the light-emitting element ED and the bank BNK between the insulating layer 116 and the second electrode CE2, but the embodiments of the present disclosure are not limited thereto. For example, the first optical layer 117a may be a diffusion layer, a sidewall diffusion layer, etc., but the embodiments of the present disclosure are not limited thereto.

The first optical layer 117a may include an organic insulation material having fine particles dispersed therein, but the embodiments of the present disclosure are not limited thereto. For example, the first optical layer 117a may be formed of siloxane having fine metal particles, such as titanium dioxide (TiO₂) particles, dispersed therein, but the embodiments of the present disclosure are not limited thereto. Light from the plurality of light-emitting elements ED may be scattered by the fine particles dispersed in the first optical layer 117a and emitted to the outside of a display device 1000. Accordingly, the first optical layer 117a can increase extraction efficiency of the light emitted from the plurality of light-emitting elements ED.

A second optical layer 117b covering the bank BNK and the first optical layer 117a may be disposed on the substrate 110 including the insulating layer 116 and the contact electrode CCE. The second optical layer 117b may be in contact with side surfaces of the first optical layer 117a to surround the first optical layer 117a. The second optical layer 117b may be disposed in an area between a plurality of pixels PX. In addition, the second optical layer 117b may be disposed to cover a part of the upper surface and side surfaces of the bank BNK.

The second optical layer 117b may be formed of an organic insulation material, but the embodiments of the present disclosure are not limited thereto. The second optical layer 117b may be formed of the same material as the first optical layer 117a, but the embodiments of the present disclosure are not limited thereto. For example, the first optical layer 117a may include fine particles, and the second optical layer 117b may not include fine particles.

Here, the contact hole 118 may be formed in an area of the second optical layer 117b, which is located on the contact electrode CCE. The contact hole 118 serves to electrically connect the second electrode CE2 disposed on the second optical layer 117b to the contact electrode CCE located below the contact hole 118. In addition, the contact hole 118 may be formed at a location overlapping the opening 116a of the insulating layer 116 disposed on the contact electrode CCE.

Referring to FIGS. 9 and 10, a distance from the side surfaces of the plurality of banks BNK to a side end of the first optical layer 117a may be defined as L1. In addition, a distance from the side end of the first optical layer 117a to a side wall adjacent to the first optical layer 117a of the contact hole 118 of the second optical layer 117b may be defined as L2.

For example, the distance L2 from the side end of the first optical layer 117a to the side wall adjacent to the first optical layer 117a of the contact hole 118 of the second optical layer 117b may be longer than the distance L1 from the side surfaces of the plurality of banks BNK to the side end of the first optical layer 117a. In addition, when the distance L1 between the bank BNK and a first optical layer 217a on a surface of a circuit layer 120 is defined as a reference value of 1, the distance L2 between the side end of the first optical layer 117a and the side wall adjacent to the first optical layer 117a of a contact hole 118 on the surface of the circuit layer 120 may range from 0.5 to 2.5. The distance L2 may preferably range from 0.8 to 2.16. In other words, the contact hole 118 is located at a distance (in some embodiments, ‘selected’ or ‘predetermined’) from the bank BNK such that the contact hole 118 and the bank BNK do not overlap with each other in a plan view. The present embodiment is not limited thereto.

Meanwhile, referring to FIGS. 10 and 11, a sidewall of the contact hole 118 of the second optical layer 117b may have at least one step 118a. The present embodiment is not limited thereto. The step 118a may include tapered portions 118a-1 and 118a-3 and a horizontal portion 118a-2 located therebetween.

In addition, among first and second tapered portions 118a-1 and 118a-3 constituting the step 118a of the contact hole 118, an upper width W2 of the first tapered portion 118a-1 located at a lower portion of the step 118a may be formed to be narrower than an upper width W3 of the second tapered portion 118a-3 located at an upper portion of the step 118a, and a lower width W1 of the first tapered portion 118a-1 may be formed to be narrower than an upper width W2 of the first tapered portion 118a-1. For example, the width may be formed to increase from the lower portion toward the upper portion of the contact hole 118.

In addition, taper angles θ1 and θ2 of the tapered portions 118a-1 and 118a-3 constituting the step 118a of the sidewall of the contact hole 118 be the same or different, for example, may form an angle of about 50 to 70 degrees and may preferably range from 60 to 70 degrees. The present embodiment is not limited thereto.

According to the present disclosure, the contact hole 118 may be formed at a location that has moved a predetermined distance from the bank BNK, and the step 118a of the sidewall of the contact hole 118 may be formed at a gentle angle. Accordingly, it is possible to prevent or reduce cracks from occurring in the second electrode CE2 disposed to be electrically connected to the contact electrode CCE through the contact hole 118.

The second electrode CE2 may be disposed on the first optical layer 117a and the second optical layer 117b. For example, the second electrode CE2 may be electrically connected to the plurality of contact electrodes CCE through the contact hole 118 of the second optical layer 117b.

A third optical layer 117c may be disposed on the second electrode CE2 to overlap the plurality of light-emitting elements ED and the first optical layer 117a that are disposed on the bank BNK. Since the third optical layer 117c is disposed above the second electrode CE2 and the plurality of light-emitting elements ED, it is possible to eliminate spots (mura) that may occur in some of the plurality of light-emitting elements ED.

Accordingly, since the light emitted from the plurality of light-emitting elements ED is uniformly diffused by the third optical layer 117c and extracted to the outside of the display device 1000, it is possible to improve luminance uniformity of the display device 1000.

For example, the third optical layer 117c may be formed of the same of different material as/from the first optical layer 117a, but the embodiments of the present disclosure are not limited thereto. For example, the third optical layer 117c may be a diffusion layer, an upper diffusion layer, etc., but the embodiments of the present disclosure are not limited thereto.

Light from the plurality of light-emitting elements ED may be scattered by the fine particles dispersed in the third optical layer 117c and emitted to the outside of the display device 1000. The third optical layer 117c may uniformly mix the light emitted from the plurality of light-emitting elements ED, thereby further improving the luminance uniformity of the display device 1000. In addition, it is possible to increase the light extraction efficiency of the display device 1000 by the light scattered by the fine particles, thereby enabling low-power driving of the display device 1000.

In the display area AA, a black matrix BM may be disposed on the second electrode CE2, the first optical layer 117a, the second optical layer 117b, and the third optical layer 117c.

In the display area AA, a cover layer 119 may be disposed on the black matrix BM.

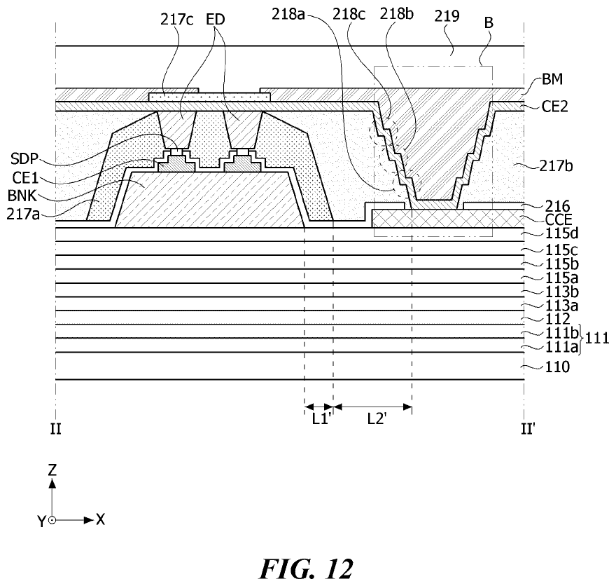

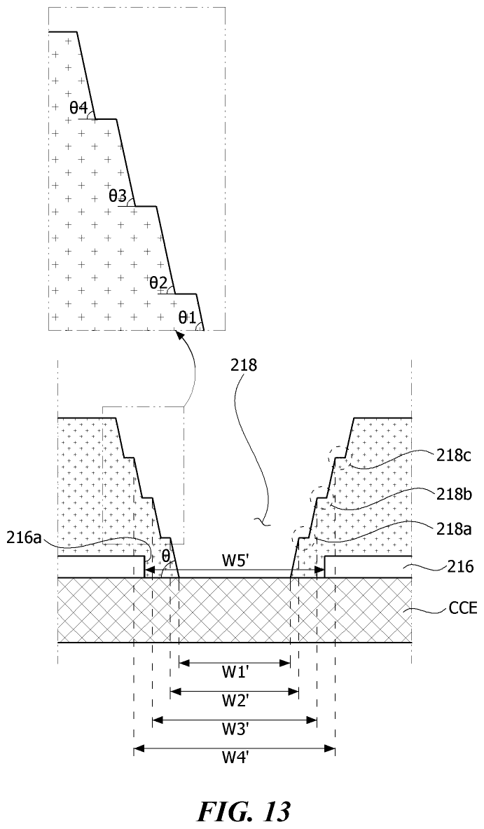

FIG. 12 is a cross-sectional view along lines II-II′ of FIG. 9 and is a cross-sectional view of a display device according to another embodiment of the present disclosure. FIG. 13 is an enlarged cross-sectional view of portion B in FIG. 12. For example, FIG. 13 is a cross-sectional view illustrating an enlarged cross-sectional structure of the contact hole 218 formed in the second optical layer 217b located on the contact electrode CCE.

In particular, another embodiment of the present disclosure may include the same configurations as the embodiment of the present disclosure of FIGS. 9 to 11 except for a cross-sectional structure of a contact hole 218 of a second optical layer 217b. Here, the cross-sectional structure of the contact hole 218 of the second optical layer 217b will be mainly described.

According to another embodiment of the present disclosure, the plurality of banks BNK may be disposed on the substrate, and the plurality of light-emitting elements ED may be disposed on the plurality of banks BNK.

Here, the first electrode CE1 may be disposed between the plurality of banks BNK and the plurality of light-emitting elements ED. The first electrode CE1 may be formed of a plurality of conductive layers. For example, the first electrode CE1 may include a first conductive layer, a second conductive layer, a third conductive layer, and a fourth conductive layer, but the embodiments of the present disclosure are not limited thereto.

For example, each of the first conductive layer, the second conductive layer, the third conductive layer, and the fourth conductive layer may be formed of molybdenum (Mo), aluminum (Al), an alloy of titanium (Ti) and indium tin oxide (ITO) or an alloy thereof, but the embodiments of the present disclosure are not limited thereto.

In addition, the signal line TL, the contact electrode CCE, and the pad electrode that are disposed on the same layer as the first electrode CE1 may be formed of multiple layers of conductive materials. The embodiments of the present disclosure are not limited thereto.

The solder pattern SDP may be disposed on the first electrode CE1 disposed below the light-emitting element ED. The solder pattern SDP may bond the light-emitting element ED to the first electrode CE1.

In addition, the contact electrode CCE formed on the same layer as the first electrode CE1 may be disposed on the substrate 110 spaced a predetermined distance from the bank BNK. The first electrode CE1 may extend to the upper surface and side surfaces of the bank BNK and may be connected to the pixel driving circuit PD (see FIG. 7) and the pad PE.

The contact electrode CCE formed on the same layer as the first electrode CE1 may be formed of a plurality of conductive layers. For example, the contact electrode CCE may include a first contact conductive layer, a second contact conductive layer, a third contact conductive layer, and a transparent conductive layer, but the embodiments of the present disclosure are not limited thereto.

For example, each of the first contact conductive layer, the second contact conductive layer, the third contact conductive layer, and the transparent conductive layer may be formed of titanium (Ti), molybdenum (Mo), aluminum (Al), an alloy of titanium (Ti) and indium tin oxide (ITO) or an alloy thereof, but the embodiments of the present disclosure are not limited thereto.

The transparent conductive layer applied as the uppermost layer of the contact electrode CCE may include a transparent conductive oxide layer, such as an ITO or IZO layer, that has corrosion resistance and acid resistance. The embodiments of the present disclosure are not limited thereto. To electrically connect the contact electrode CCE to the second electrode CE2, the contact electrode CCE and the second electrode CE2 may be electrically connected through the contact hole 218 formed in the second optical layer 217b disposed on the contact electrode CCE.

An insulating layer 216 may be disposed on the plurality of banks BNK, the first electrode CE1, and the contact electrode CCE. Specifically, the insulating layer 216 that serves as a passivation layer may be disposed on a plurality of signal lines TL, a plurality of first electrodes CE1, a plurality of contact electrodes CCE, and the fourth organic insulating layer 115d. For example, since the insulating layer 216 is disposed to cover the remaining areas not including the bending area BA and areas in which the plurality of pads PE and the solder pattern SDP are disposed, it is possible to reduce the penetration of foreign matters such as moisture or impurities into the light-emitting element ED.

Referring to FIG. 13, in the insulating layer 216, an opening 216a may be formed on a portion of the contact electrode CCE disposed to be spaced a predetermined distance from the bank BNK. A width W5′ of the opening 216a may be greater than a width W1′ of a lower side of the contact hole 218 formed in the second optical layer 217b. For example, an area of the opening 116a may be greater than an area of a lower side of the contact hole 218. Accordingly, by forming the opening 216a by removing a portion of the insulating layer 216 located in a contact hole formation area for connecting the second electrode CE2 to the contact electrode CCE, it is possible to secure a formation margin of the contact hole 218 and improve misalignment of the contact hole 218.

The first optical layer 217a may be disposed on the insulating layer 216 covering the plurality of light-emitting elements ED on the bank BNK. For example, the first optical layer 217a may be disposed to cover the plurality of light-emitting elements ED and the bank BNK. For example, the first optical layer 217a may cover spaces between the bank BNK, a part of the insulating layer 116, and the plurality of light-emitting elements ED. The first optical layer 217a may be disposed between the plurality of light-emitting elements ED and between the plurality of banks BNK, which are included in one pixel PX, or may cover the plurality of light-emitting elements ED and the plurality of banks BNK. For example, the first optical layer 217a may be disposed to surround side portions of the light-emitting element ED and the bank BNK between the insulating layer 216 and the second electrode CE2, but the embodiments of the present disclosure are not limited thereto.

The first optical layer 217a may include an organic insulation material having fine particles dispersed therein, but the embodiments of the present disclosure are not limited thereto. Light from the plurality of light-emitting elements ED may be scattered by the fine particles dispersed in the first optical layer 217a and emitted to the outside of a display device 1000. Accordingly, the first optical layer 217a can increase the extraction efficiency of the light emitted from the plurality of light-emitting elements ED.

The second optical layer 217b covering the first optical layer 217a may be disposed on the substrate 110 including the insulating layer 216 and the contact electrode CCE. The second optical layer 217b may be in contact with the side surfaces of the first optical layer 217a to surround the first optical layer 217a. The second optical layer 217b may be disposed in an area between a plurality of pixels PX. In addition, the second optical layer 217b may be disposed to cover a part of the upper surface and side surfaces of the bank BNK.

The second optical layer 217b may be formed of an organic insulation material, but the embodiments of the present disclosure are not limited thereto. The second optical layer 217b may be formed of the same or different material as/from the first optical layer 217a, but the embodiments of the present disclosure are not limited thereto.

Here, the contact hole 218 may be formed in an area of the second optical layer 217b, which is located on the contact electrode CCE. The contact hole 218 serves to electrically connect the second electrode CE2 disposed on the second optical layer 217b to the contact electrode CCE located below the contact hole 218. In addition, the contact hole 218 may be formed at a location overlapping the opening 216a of the insulating layer 216 disposed on the contact electrode CCE.

Referring to FIGS. 12 and 13, a distance from the side surfaces of the plurality of banks BNK to the side end of the first optical layer 217a may be defined as L1′. In addition, a distance from the side end of the first optical layer 217a to a side wall adjacent to the first optical layer 217a of the contact hole 218 of the second optical layer 217b may be defined as L2′.

For example, the distance L2′ from the side end of the first optical layer 217a to the side wall adjacent to the first optical layer 217a of the contact hole 218 of the second optical layer 217b may be longer than the distance L1′ from the side surfaces of the plurality of banks BNK to the side end of the first optical layer 217a. In addition, when the distance L1′ between the side surface of the bank BNK and the side end of the first optical layer 217a on the surface of the circuit layer 120 is defined as a reference value of 1, the distance L2′ between a side end of the first optical layer 217a and the side wall adjacent to the first optical layer 217a of the contact hole 217b-1 on the surface of the circuit layer 120 may range from 0.5 to 2.5 and preferably range from 0.8 to 2.16. The present embodiment is not limited thereto.

Meanwhile, referring to FIGS. 12 and 13, each of a plurality of steps 218a, 218b, and 218c of the sidewall of the contact hole 218 of the second optical layer 217b may include a plurality of tapered portions and horizontal portions located therebetween.

A width W1′ of a lower side of a tapered portion of a first step 218a of the sidewall of the contact hole 218 may be formed to be narrower than widths W2′, W3′, and W4′ of the lower sides of tapered portions of second and third steps 218b and 218c and the upper side of the tapered portion of the third step 218c. For example, the width may be formed to increase from the first step 218a to the third step 218c of the sidewall of the contact hole 218. In addition, taper angles θ of the steps 218a, 218b, and 218c of the sidewall of the contact hole 218 may range from about 50 to 70 degrees and preferably range from 60 to 70 degrees. The present embodiment is not limited thereto.

According to another embodiment of the present disclosure, the contact hole 218 may be formed at a location further spaced apart from the bank BNK than before, and the plurality of steps 218a, 218b, and 218c are formed at a gentle angle, for example, about 50 to 70 degrees, thereby preventing or reducing cracks from occurring in the second electrode CE2 disposed to be electrically connected to the contact electrode CCE through the contact hole 218.

In addition, the width W1′ of a lower side of the lower step 218a of the contact hole 218 may be smaller than a width W5′ of the opening 216a of the insulating layer 216 disposed on the contact electrode CCE.

The second electrode CE2 may be disposed on the first optical layer 217a and the second optical layer 217b. For example, the second electrode CE2 may be electrically connected to the plurality of contact electrodes CCE through the contact hole 218 of the second optical layer 217b.

A third optical layer 217c may be disposed on the second electrode CE2 to overlap the plurality of light-emitting elements ED and the first optical layer 217a that are disposed on the bank BNK. Since the third optical layer 217c is disposed above the second electrode CE2 and the plurality of light-emitting elements ED, it is possible to eliminate spots (mura) that may occur in some of the plurality of light-emitting elements ED.

Accordingly, since the light emitted from the plurality of light-emitting elements ED is uniformly diffused by the third optical layer 217c and extracted to the outside of the display device 1000, it is possible to improve the luminance uniformity of the display device 1000.

For example, the third optical layer 217c may be formed of the same or different material as/from the first optical layer 217a, but the embodiments of the present disclosure are not limited thereto.

Light from the plurality of light-emitting elements ED may be scattered by the fine particles dispersed in the third optical layer 217c and emitted to the outside of the display device 1000. The third optical layer 217c may uniformly mix the light emitted from the plurality of light-emitting elements ED, thereby further improving the luminance uniformity of the display device 1000. In addition, it is possible to increase the light extraction efficiency of the display device 1000 by the light scattered by the fine particles, thereby enabling the low-power driving of the display device 1000.

In the display area AA, the black matrix BM may be disposed on the second electrode CE2, the first optical layer 217a, the second optical layer 217b, and the third optical layer 217c. In the display area AA, a cover layer 219 may be disposed on the black matrix BM.

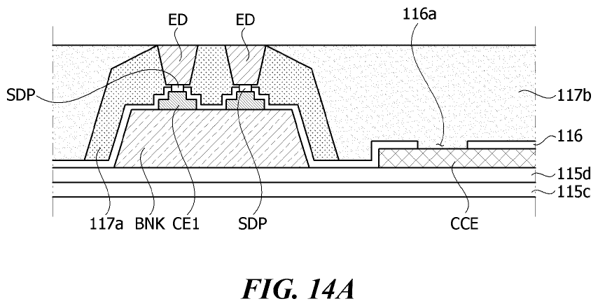

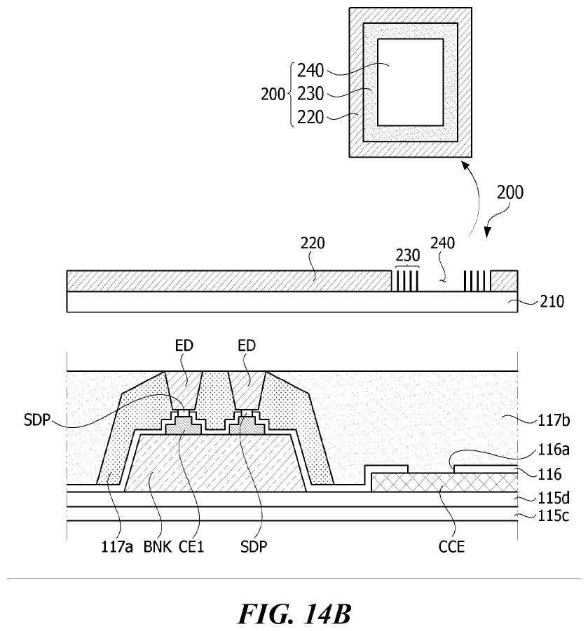

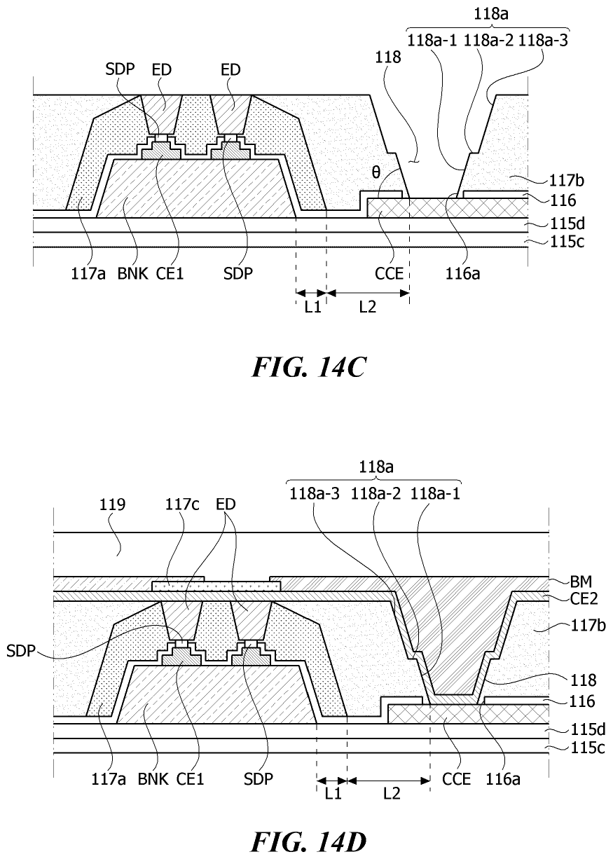

FIGS. 14A to 14D are cross-sectional views of a manufacturing process of a display device according to an embodiment of the present disclosure.

According to a manufacturing process of a display device according to an embodiment of the present disclosure, referring to FIG. 14A, first, the substrate 110 on which a buffer layer 111, a pixel driving circuit PD, a plurality of protective layers 113a and 113b, connection lines 121 and 122, and a plurality of organic insulating layers 115a, 115b, 115c, and 115d are disposed may be prepared.

Next, a plurality of banks BNK may be formed on the fourth organic insulating layer 115d disposed on the substrate 110.

Subsequently, the first electrode CE1 may be disposed on the plurality of banks BNK, and the contact electrode CCE may be disposed on the fourth organic insulating layer 115d disposed at a location spaced a predetermined distance from the plurality of banks BNK.

In this case, the first electrode CE1 may be formed of a plurality of conductive layers. For example, the first electrode CE1 may include a first conductive layer, a second conductive layer, a third conductive layer, and a fourth conductive layer, but the embodiments of the present disclosure are not limited thereto.

For example, each of the first conductive layer, the second conductive layer, the third conductive layer, and the fourth conductive layer may be formed of molybdenum (Mo), aluminum (Al), an alloy of titanium (Ti) and indium tin oxide (ITO), or an alloy thereof, but the embodiments of the present disclosure are not limited thereto.

The signal line TL, the contact electrode CCE, and the pad electrode PE (see FIG. 7) that are disposed on the same layer as the first electrode CE1 may be formed of multiple layers of conductive materials. The embodiments of the present disclosure are not limited thereto.

The first electrode CE1 may extend to the upper surface and side surfaces of the bank BNK and may be connected to the pixel driving circuit PD (see FIG. 7) and the pad PE.

Subsequently, the solder pattern SDP may be disposed on the first electrode CE1 disposed below the light-emitting element ED. The solder pattern SDP may bond the light-emitting element ED to the first electrode CE1. The first electrode CE1 and the light-emitting element ED may be electrically connected through eutectic bonding using the solder pattern SDP, but the embodiments of the present disclosure are not limited thereto.

Next, the insulating layer 116 may be disposed on the plurality of banks BNK, the first electrode CE1, and the contact electrode CCE. Specifically, the insulating layer 116 that serves as a passivation layer may be disposed on a plurality of signal lines TL, a plurality of first electrodes CE1, a plurality of contact electrodes CCE, and the fourth organic insulating layer 115d.

Since the insulating layer 116 is disposed to cover the remaining areas not including the bending area BA and areas in which the plurality of pads PE and the solder pattern SDP are disposed, it is possible to reduce the penetration of foreign matters such as moisture or impurities into the light-emitting element ED. For example, the insulating layer 116 may be formed of a single layer or multiple layers of silicon oxide (SiOₓ), silicon nitride (SiNₓ) or silicon oxynitride (SiOₓN_{y}) that is an inorganic film material, but the embodiments of the present disclosure are not limited thereto.

Subsequently, the insulating layer 116 may be selectively removed through a masking process using photolithography technology to form a hole (not illustrated) and the opening 116a that expose the upper surface of the solder pattern SDP in contact with the light-emitting element ED and a part of the upper surface of the contact electrode CCE, respectively.

In this case, the width W4 of the opening 116a may be greater than the width W1 of the lower side of the contact hole 118 formed in the second optical layer 117b. For example, the area of the opening 116a may be greater than the area of the lower side of the contact hole 118. Accordingly, by forming the opening 116a by removing a portion of the insulating layer 116 located in a contact hole formation area for connecting the second electrode CE2 to the contact electrode CCE, it is possible to secure a formation margin of the contact hole 118 and improve misalignment of the contact hole 118.

Next, a plurality of light-emitting elements ED may be transferred onto the first electrode CE1 on the bank BNK and may be in electrical contact with the first electrode CE1 via the solder pattern SDP.

Next, the first optical layer 117a may be disposed on the insulating layer 116 covering the plurality of light-emitting elements ED. For example, the first optical layer 117a may be disposed to cover the plurality of light-emitting elements ED and the banks BNK. The first optical layer 117a may cover spaces between the banks BNK, a part of the insulating layer 116, and the plurality of light-emitting elements ED. The first optical layer 117a may be disposed between the plurality of light-emitting elements ED and between the plurality of banks BNK, which are included in one pixel PX, or may cover the plurality of light-emitting elements ED and the plurality of banks BNK. For example, the first optical layer 117a may be disposed to surround side portions of the light-emitting element ED and the banks BNK between the insulating layer 116 and the second electrode CE2, but the embodiments of the present disclosure are not limited thereto.

The first optical layer 117a may include an organic insulation material having fine particles dispersed therein, but the embodiments of the present disclosure are not limited thereto. For example, the first optical layer 117a may be formed of siloxane having fine metal particles, such as titanium dioxide (TiO₂) particles, dispersed therein, but the embodiments of the present disclosure are not limited thereto. Light from the plurality of light-emitting elements ED may be scattered by the fine particles dispersed in the first optical layer 117a and emitted to the outside of a display device 1000. Accordingly, the first optical layer 117a can increase the extraction efficiency of the light emitted from the plurality of light-emitting elements ED.

Subsequently, the second optical layer 117b covering the bank BNK and the first optical layer 117a may be disposed on the substrate 110 including the insulating layer 116 and the contact electrode CCE. In this case, the second optical layer 117b may be in contact with the side surfaces of the first optical layer 117a to surround the first optical layer 117a. The second optical layer 117b may be disposed in areas between a plurality of pixels PX. In addition, the second optical layer 117b may be disposed to cover a part of the upper surface and side surfaces of the bank BNK.

The second optical layer 117b may be formed of an organic insulation material, but the embodiments of the present disclosure are not limited thereto. The second optical layer 117b may be formed of the same material as the first optical layer 117a, but the embodiments of the present disclosure are not limited thereto. For example, the first optical layer 117a may include fine particles, and the second optical layer 117b may not include fine particles.

Next, referring to FIG. 14B, a half tone mask 200 may be disposed above the first and second optical layers 117a and 117b. The half tone mask 200 may be a mask in which areas with different transmittances exist within a single mask. The present embodiment is not limited thereto. The half tone mask 200 may have a light-blocking layer 220 that completely blocks light on a transparent substrate 210, a semi-transmissive layer 230, and a transmissive area 240. In this case, the semi-transmissive layer 230 may form a plurality of light-blocking layers to form a plurality of micropatterns or form a semi-transmissive film to form a light-blocking layer. The present embodiment is not limited thereto.

Subsequently, referring to FIG. 14C, after performing an exposure and development process using a photolithography technique, a part of the second optical layer 117b located on the contact electrode CCE may be selectively removed to form the contact hole 118 exposing an upper surface of the contact electrode CCE. In this case, the contact hole 118 serves to electrically connect the second electrode CE2 disposed on the second optical layer 117b to the contact electrode CCE located below the contact hole 118. The contact hole 118 may be formed at a location overlapping the opening 116a of the insulating layer 116 disposed on the contact electrode CCE.

Since a portion of the second optical layer 117b, which is disposed below the semi-transmissive layer 230, has a lower light transmittance than a portion located below the transmissive area 240 during exposure, the second optical layer 117b has a predetermined thickness that remains without being removed during development. In this way, during exposure and development using the half tone mask 200, the sidewall of the contact hole 118 may form the step 118a. In this case, the step 118a may include a tapered portion and a horizontal portion. For example, the tapered portion may include the first tapered portion 118a-1 and the second tapered portion 118a-3. The horizontal portion 118a-2 may be formed between the first and second tapered portions 118a-1 and 118a-3. The present embodiment is not limited thereto.

The tapered portions constituting the step 118a are not limited to the first and second tapered portions 118a-1 and 118a-3 and may include two or more tapered portions. In addition, the horizontal portion 118a-2 is not limited to one horizontal portion 118a-2 and may include at least one horizontal portion.

Among the first and second tapered portions 118a-1 and 118a-3 constituting the step 118a of the contact hole 118, the lower width W1 of the first tapered portion 118a-1 located at the lower portion of the step 118a may be formed to be narrower than the upper width W3 of the second tapered portion 118a-3 located at the upper portion of the step 118a. For example, the step 118a of the sidewall of the contact hole 118 may be formed to have a width that increases from the lower tapered portion to the upper tapered portion.

The taper angle θ of the step 118a of the sidewall of the contact hole 118 may range from about 50 to 70 degrees and preferably range from 60 to 70 degrees. The present embodiment is not limited thereto.

For example, the distance from the side surfaces of the plurality of banks BNK to the side end of the first optical layer 117a may be defined as L1. In addition, the distance from the side end of the first optical layer 117a to the side wall adjacent to the first optical layer 117a of the contact hole 118 of the second optical layer 117b may be defined as L2. In addition, the distance from the side surfaces of the plurality of banks BNK to the side wall adjacent to the first optical layer 117a of the contact hole 118 of the second optical layer 117b may be defined as L3.

The distance L2 from the side end of the first optical layer 117a to the side wall adjacent to the first optical layer 117a of the contact hole 118 of the second optical layer 117b may be longer than the distance L1 from the side surfaces of the plurality of banks BNK to the side end of the first optical layer 117a. In addition, when the distance L1 between the bank BNK and the first optical layer 117a on the surface of the circuit layer 120 (see FIG. 8) is defined as a reference value of 1, the distance L2 between the side end of the first optical layer 117a and the side wall adjacent to the first optical layer 117a of a contact hole 118 on the surface of the circuit layer 120 may range from 0.5 to 2.5. The distance L2 may preferably range from 0.8 to 2.16. The present embodiment is not limited thereto.

According to the present disclosure, since the contact hole 118 is formed at a location further spaced apart from the bank BNK than before, and the step 118a may be formed at a gentle angle, it is possible to prevent or reduce cracks from occurring in the second electrode CE2 disposed to be electrically connected to the contact electrode CCE through the contact hole 118.

In addition, the width W1 of the lower side of the step 118a of the sidewall of the contact hole 118 may be smaller than the width W4 of the opening 116a of the insulating layer 116 disposed on the contact electrode CCE.

Next, referring to FIG. 14D, the second electrode CE2 may be disposed on the first optical layer 117a and the second optical layer 117b. For example, the second electrode CE2 may be electrically connected to the plurality of contact electrodes CCE through contact hole 118 of the second optical layer 117b.

Subsequently, the third optical layer 117c may be disposed on the second electrode CE2 to overlap the plurality of light-emitting elements ED and the first optical layer 117a that are disposed on the bank BNK. Since the third optical layer 117c is disposed above the second electrode CE2 and the plurality of light-emitting elements ED, it is possible to eliminate spots (mura) that may occur in some of the plurality of light-emitting elements ED.

Next, in the display area AA, the black matrix BM may be disposed on the second electrode CE2, the first optical layer 117a, the second optical layer 117b, and the third optical layer 117c.

Subsequently, in the display area AA, the cover layer 119 may be disposed on the black matrix BM.

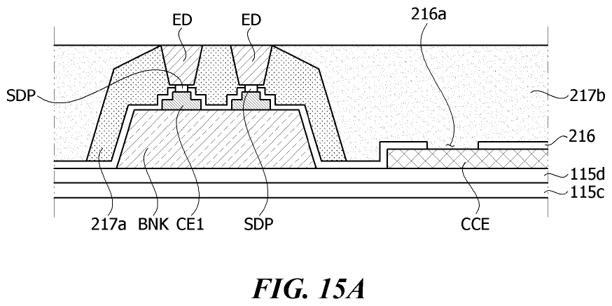

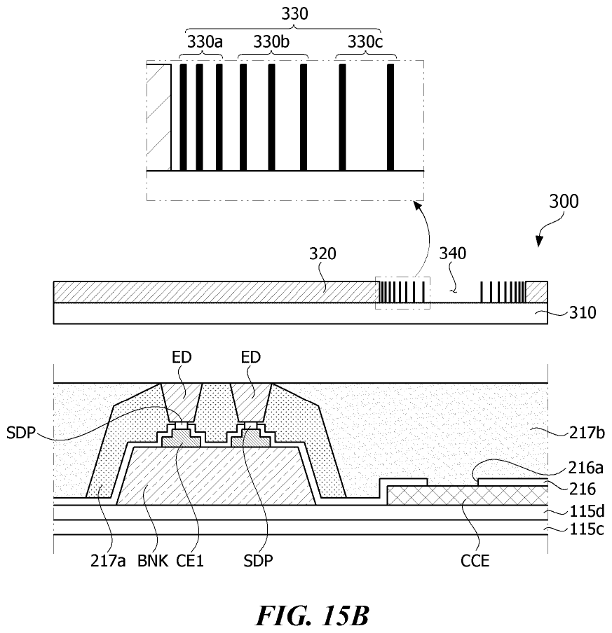

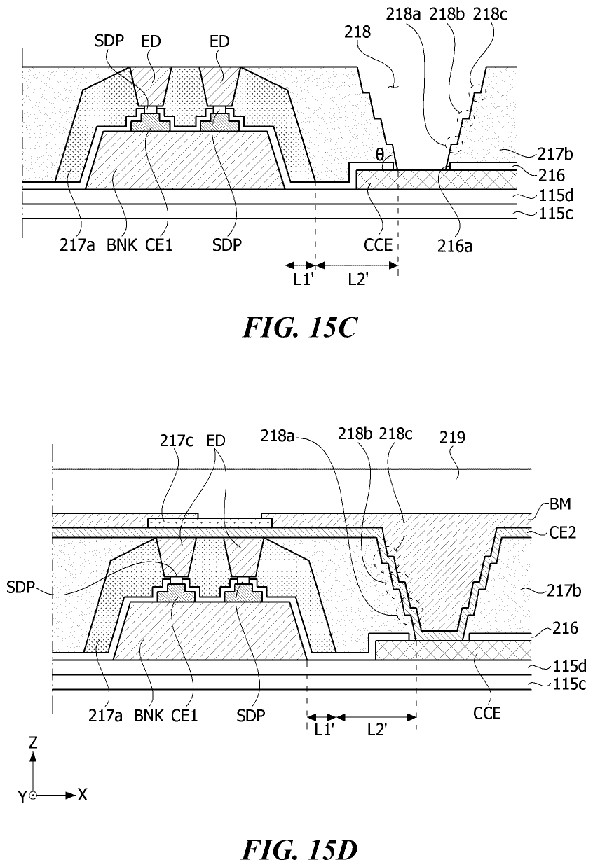

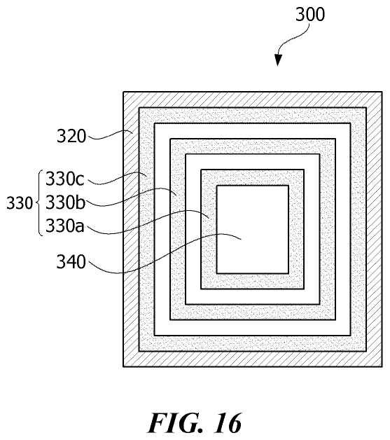

FIGS. 15A to 15D are cross-sectional views of a manufacturing process of a display device according to another embodiment of the present disclosure. FIG. 16 is a plan view illustrating a half tone mask during the manufacturing of a display device according to another embodiment of the present disclosure.

Another embodiment of the present disclosure may be composed of the same processes as the embodiment of FIGS. 14A to 14D except for a process of forming a contact hole using a half tone mask of a different form. Hereinafter, the process of forming a contact hole using a half tone mask of a different form will be mainly described.

According to a manufacturing process of a display device according to another embodiment of the present disclosure, referring to FIG. 15A, first, the substrate 110 on which the buffer layer 111, the pixel driving circuit PD, the plurality of protective layers 113a and 113b, the connection lines 121 and 122, and the plurality of organic insulating layers 115a, 115b, 115c, and 115d are disposed may be prepared.

Next, a plurality of banks BNK may be formed on the fourth organic insulating layer 115d disposed on the substrate 110.

Subsequently, the first electrode CE1 may be disposed on the plurality of banks BNK, and the contact electrode CCE may be disposed on the fourth organic insulating layer 115d disposed at a location spaced a predetermined distance from the plurality of banks BNK. The signal line TL, the contact electrode CCE, and the pad electrode PE (see FIG. 7) that are disposed on the same layer as the first electrode CE1 may be formed of multiple layers of conductive materials. The embodiments of the present disclosure are not limited thereto.

In addition, the first electrode CE1 may extend to the upper surface and side surfaces of the bank BNK and may be connected to the pixel driving circuit PD (see FIG. 7) and the pad PE.

Subsequently, the solder pattern SDP may be disposed on the first electrode CE1 disposed below the light-emitting element ED. The solder pattern SDP may bond the light-emitting element ED to the first electrode CE1. The first electrode CE1 and the light-emitting element ED may be electrically connected through eutectic bonding using the solder pattern SDP, but the embodiments of the present disclosure are not limited thereto.

Next, the insulating layer 216 may be disposed on the plurality of banks BNK, the first electrode CE1, and the contact electrode CCE. Specifically, the insulating layer 216 that serves as a passivation layer may be disposed on a plurality of signal lines TL, a plurality of first electrodes CE1, a plurality of contact electrodes CCE, and the fourth organic insulating layer 115d. In addition, since the insulating layer 216 is disposed to cover the remaining areas not including the bending area BA and areas in which the plurality of pads PE and the solder pattern SDP are disposed, it is possible to reduce the penetration of foreign matter such as moisture or impurities into the light-emitting element ED. For example, the insulating layer 216 may be formed of a single layer or multiple layers of silicon oxide (SiOₓ), silicon nitride (SiNₓ) or silicon oxynitride (SiOₓN_{y}) that is an inorganic film material, but the embodiments of the present disclosure are not limited thereto.

Subsequently, the insulating layer 216 may be selectively removed through a mask process using a photolithography technology to form a hole (not illustrated) and the opening 216a that expose the upper surface of the solder pattern SDP in contact with the light-emitting element ED and a part of the upper surface of the contact electrode CCE, respectively.

In this case, the width W5′ of the opening 216a may be greater than the width W1′ of the lower side of the contact hole 218 formed in the second optical layer 217b. For example, the area of the opening 216a may be greater than the area of the lower side of the contact hole 218. Accordingly, by forming the opening 216a by removing a portion of the insulating layer 216 located in a contact hole formation area for connecting the second electrode CE2 to the contact electrode CCE, it is possible to secure a formation margin of the contact hole 218 and improve misalignment of the contact hole 218.

Next, a plurality of light-emitting elements ED may be transferred onto the first electrode CE1 on the bank BNK and may be in electrical contact with the first electrode CE1 via the solder pattern SDP.

Next, the first optical layer 217a may be disposed on the insulating layer 216 covering the plurality of light-emitting elements ED. For example, the first optical layer 217a may be disposed to cover the plurality of light-emitting elements ED and the bank BNK. The first optical layer 217a may cover spaces between the bank BNK, a part of the insulating layer 216, and the plurality of light-emitting elements ED.

Next, the second optical layer 217b covering the bank BNK and the first optical layer 217a may be disposed on the substrate 110 including the insulating layer 216 and the contact electrode CCE. In this case, the second optical layer 217b may be in contact with the side surfaces of the first optical layer 217a to surround the first optical layer 217a. The second optical layer 217b may be disposed in an area between a plurality of pixels PX. In addition, the second optical layer 217b may be disposed to cover a part of the upper surface and side surfaces of the bank BNK. The second optical layer 217b may be formed of an organic insulation material, but the embodiments of the present disclosure are not limited thereto.

Next, referring to FIGS. 15B and 16, a half tone mask 300 may be disposed above the first and second optical layers 217a and 217b. The present embodiment is not limited thereto. The half tone mask 300 may have a light-blocking layer 320 that completely blocks light, a semi-transmissive layer 330, and a transmissive area 340 on a transparent substrate 310. In this case, the plurality of semi-transmissive layers 330 may include a plurality of semi-transmissive patterns 330a, 330b, and 330c. The present embodiment is not limited thereto. In addition, gaps between the plurality of semi-transmissive patterns 330a, 330b, and 330c may be formed to gradually increase toward a central portion of the semi-transmissive layer 330. For example, the gaps between the first semi-transmissive patterns 330c may be formed to be greater than the gaps between the second semi-transmissive patterns 330b and the gaps between the third semi-transmissive patterns 330a. In addition, the gaps between the second semi-transmissive patterns 330b may be formed to be greater than the gaps between the third semi-transmissive patterns 330a. Accordingly, through a difference in the transmittance of light passing through the plurality of semi-transmissive patterns 330a, 330b, and 330c, a difference in thickness and width of the second optical layer 217b removed subsequent exposure and development may occur. The present embodiment is not limited thereto.

Subsequently, referring to FIG. 15C, after performing an exposure and development process using a photolithography technique, a part of the second optical layer 217b located on the contact electrode CCE may be selectively removed to form the contact hole 218 exposing the upper portion of the contact electrode CCE. In this case, the contact hole 218 serves to electrically connect the second electrode CE2 disposed on the second optical layer 217b to the contact electrode CCE located below the contact hole 218. In addition, the contact hole 218 may be formed at a location overlapping the opening 216a of the insulating layer 216 disposed on the contact electrode CCE. For example, the lower side of the contact hole 218 may be formed to be located in the opening 216a of the insulating layer 216.

Since a portion of the second optical layer 217b, which is disposed below the semi-transmissive layer 330, has a lower light transmittance during exposure than a portion of the second optical layer 217b, which is located below the transmissive area 340, the second optical layer 117b has a predetermined thickness that remains without being removed during development. In this way, the contact hole 218 may be formed by selectively removing the second optical layer 217b through exposure and development using the half tone mask 300. The contact hole 218 may include the plurality of steps 218a, 218b, and 218c. Each of the plurality of steps 218a, 218b, and 218c may have a plurality of tapered portions and horizontal portions. In this case, the second optical layer 217b is formed to have a great thickness so that the tapered portion having a shape tapered at a predetermined angle rather than a vertical cross-sectional shape may be formed during exposure and development using the half tone mask 300. The present embodiment is not limited thereto. For example, each of the plurality of steps 218a, 218b, and 218c may include a plurality of tapered portions and horizontal portions. In this case, the plurality of steps 218a, 218b, and 218c may be formed through exposure and development using the first to third semi-transmissive patterns 330a-330c.

The plurality of steps 218a, 218b, and 218c may include a plurality of tapered portions and horizontal portions. For example, the tapered portions and horizontal portions constituting the step may be adjusted according to the design of the plurality of semi-transmissive patterns 330 of the half tone mask 300.

In addition, a width W2′ of the tapered portion of the first step 218a located at the lower portion of the contact hole 218 among the steps 218a, 218b, and 218c of the sidewall of the contact hole 218 may be formed to be narrower than a width W4′ of the tapered portion of the third step 218c located at the uppermost portion of the contact hole 218. For example, the width may be formed to increase from the lower tapered portion to the upper tapered portion of the contact hole 218.

In addition, the taper angles θ (e.g., θ1, θ2, θ3, and θ4) (see FIG. 13) of the steps 218a, 218b, and 218c of the sidewall of the contact hole 218 may range from about 50 to 70 degrees and preferably range from 60 to 70 degrees. The present embodiment is not limited thereto.

For example, the distance from the side surfaces of the plurality of banks BNK to a side end of the first optical layer 217a may be defined as L1′. In addition, the distance from the side end of the first optical layer 217a to a side wall adjacent to the first optical layer 217a of the contact hole 218 of the second optical layer 217b may be defined as L2′. In addition, the distance from the side surfaces of the plurality of banks BNK to the side wall adjacent to the first optical layer 217a of the contact hole 218 of the second optical layer 217b may be defined as L3′.

For example, the distance L2′ from the side end of the first optical layer 217a to a side wall adjacent to the first optical layer 217a of the contact hole 218 of the second optical layer 217b may be greater than the distance L1′ from the side surfaces of the plurality of banks BNK to the side end of the first optical layer 217a. In addition, when the distance L1′ between the bank BNK and a first optical layer 217a on a surface of a circuit layer 120 is defined as a reference value of 1, the distance L2′ between the side end of the first optical layer 217a and the side wall adjacent to the first optical layer 217a of a contact hole 218 on the surface of the circuit layer 120 may range from 0.5 to 2.5. The distance L2 may preferably range from 0.8 to 2.16. The present embodiment is not limited thereto.

According to the present disclosure, since the contact hole 218 is formed at a location further spaced apart from the bank BNK than before, and the plurality of steps 218a, 218b, and 218c are formed at gentle angles, it is possible to prevent or reduce cracks from occurring in the second electrode CE2 disposed to be electrically connected to the contact electrode CCE through the contact hole 218.

In addition, the width W1′ of the lower side of the contact hole 218 may be smaller than the width W5′ of the opening 216a of the insulating layer 216 disposed on the contact electrode CCE.

Next, referring to FIG. 15D, the second electrode CE2 may be disposed on the first optical layer 217a and the second optical layer 217b. For example, the second electrode CE2 may be electrically connected to the plurality of contact electrodes CCE through the contact hole 218 of the second optical layer 217b.

Subsequently, the third optical layer 217c may be disposed on the second electrode CE2 to overlap the plurality of light-emitting elements ED and the first optical layer 217a that are disposed on the bank BNK. Since the third optical layer 217c is disposed above the second electrode CE2 and the plurality of light-emitting elements ED, it is possible to eliminate spots (mura) that may occur in some of the plurality of light-emitting elements ED.

Next, in the display area AA, the black matrix BM may be disposed on the second electrode CE2, the first optical layer 217a, the second optical layer 217b, and the third optical layer 217c.

Subsequently, in the display area AA, the cover layer 219 may be disposed on the black matrix BM.

According to the present disclosure, by moving a formation location of the contact hole used for connecting the contact electrode to the cathode to be spaced a predetermined distance from the side end of the optical layer and forming a cross-sectional structure of the contact hole to have a gentle taper using a half tone mask, it is possible to prevent or reduce cracks from occurring in a cathode when the contact electrode and the second electrode, that is, the cathode, are connected through the contact hole.

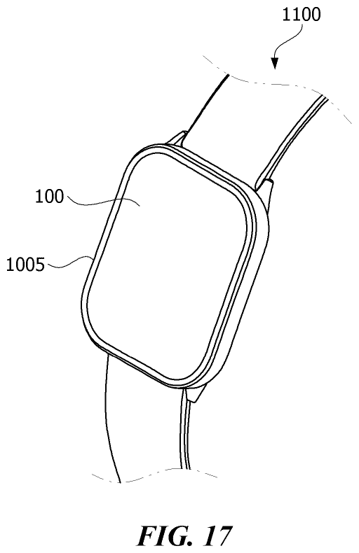

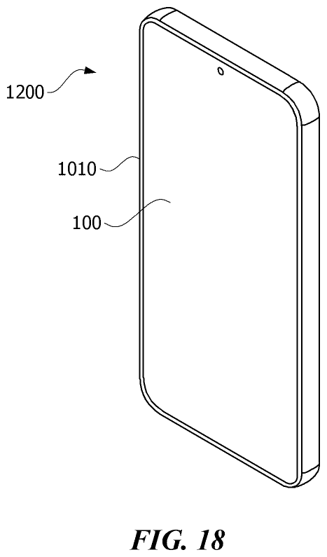

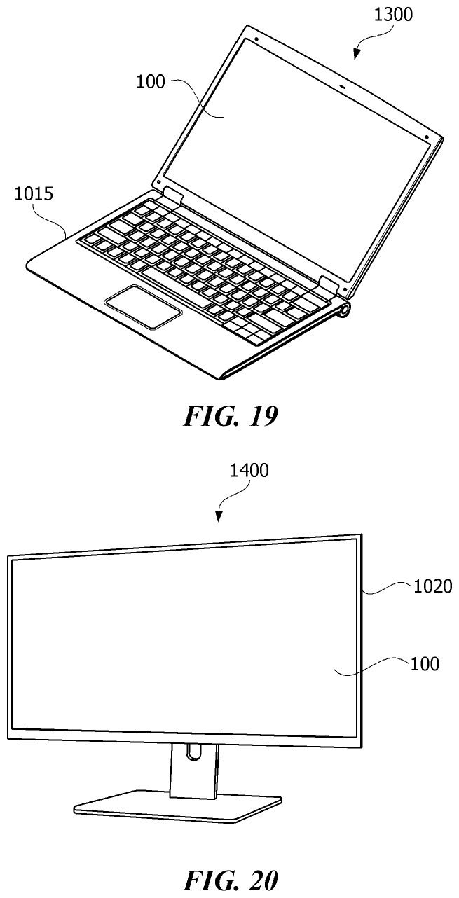

FIGS. 17 to 20 are views illustrating devices to which the display devices according to the embodiments of the present disclosure are applied.

Referring to FIGS. 17 to 20, the display device 1000 according to embodiments of the present disclosure may be included in various devices or electronic devices. For example, referring to FIGS. 17 to 20, various electronic devices may include a wearable device 1100, a mobile device 1200, a notebook 1300, and a monitor or TV 1400, but the embodiments of the present disclosure are not limited thereto.

The wearable device 1100, the mobile device 1200, the notebook 1300, and the monitor or TV 1400 may include case units 1005, 1010, 1015, and 1020, respectively, and the display panel 100 and the display device 1000 according to the embodiments of the present disclosure, which are described in FIGS. 1 to 16.

The display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more embodiments of the present disclosure may be applied to an organic light emitting lighting device or an inorganic light emitting lighting device.

According to the present disclosure, by moving a formation location of a contact hole used for connecting a contact electrode to a cathode to be spaced a predetermined distance from a side end of an optical layer and forming a cross-sectional structure of the contact hole to have a gentle taper using a half tone mask, it is possible to prevent or reduce cracks from occurring in a cathode when a contact electrode and the cathode are connected through a contact hole.

Effects of the present disclosure are not limited to the above-described effects, and other effects that are not mentioned will be able to be clearly understood by those skilled in the art to which the present disclosure pertains from the following description.

The display device according to various embodiments of the present disclosure may be described as follows.

A display device according to various embodiments of the present disclosure may comprise a substrate; a circuit layer disposed on the substrate; a plurality of banks disposed on the circuit layer; one or more light-emitting elements disposed one-to-one on the banks and each having a first electrode and a second electrode; a contact electrode disposed on the circuit layer to be spaced apart from the banks; a first optical layer covering the banks and the one or more light-emitting elements disposed on the banks; and a second optical layer covering the first optical layer and having a contact hole exposing a part of the contact electrode, wherein, when a distance between the bank and the first optical layer on a surface of the circuit layer is defined as a reference value of 1, a distance between the first optical layer and the contact hole on the surface of the circuit layer ranges from 0.5 to 2.5.

According to one embodiment of the present disclosure, the contact hole 118 is located at a distance (in some embodiments, ‘selected’ or ‘predetermined’) from the bank BNK such that the contact hole 118 and the bank BNK do not overlap with each other in a plan view. Here, the contact hole 118 is located at the distance from the bank BNK such that cracking in the second electrode is reduced during use. “During use” includes mechanical stress scenarios such as bending, folding, or thermal cycling that occur during normal operation and handling of the display device. It also includes during the connection process when the contact electrode and the cathode are connected through the contact hole.

According to one embodiment of the present disclosure, a sidewall of the contact hole may have one or more steps.

According to one embodiment of the present disclosure, a tapered portion of the contact hole may have a taper angle of 50 to 70 degrees.

According to one embodiment of the present disclosure, the first electrode may include a plurality of conductive layers and a transparent conductive layer that is an uppermost layer, and the contact electrode includes a transparent conductive layer in an uppermost portion excluding a portion below the contact hole in contact with the second electrode along with the plurality of conductive layers.

According to one embodiment of the present disclosure, the plurality of conductive layers may include a first electrode conductive layer, a reflective conductive layer, and a second electrode conductive layer, and the transparent conductive layer includes indium tin oxide (ITO).

According to one embodiment of the present disclosure, insulating layers may be disposed between the light-emitting element and the optical layer and between the first electrode and the contact electrode.

According to one embodiment of the present disclosure, the insulating layer may have an opening spaced apart from a side surface of the contact hole of the optical layer.

According to one embodiment of the present disclosure, the display device may further include a third optical layer disposed on the second electrode on the plurality of light-emitting elements.

According to one embodiment of the present disclosure, the display device may further include a black matrix disposed on the second electrode including the third optical layer and having a plurality of transmissive holes; and a cover layer disposed on the black matrix.

According to one embodiment of the present disclosure, the circuit layer may further include a pixel driving circuit disposed on the substrate and electrically connected to the plurality of light-emitting elements and the contact electrode; and a plurality of signal lines electrically connecting the first electrode to the pixel driving circuit.

A display device according to various embodiments of the present disclosure may comprise a substrate; a circuit layer disposed on the substrate; a plurality of banks disposed on the circuit layer; one or more light-emitting elements disposed one-to-one on the banks and each having a first electrode and a second electrode; a contact electrode disposed on the circuit layer to be spaced apart from the banks; a first optical layer covering the banks and the one or more light-emitting elements disposed on the banks; and a second optical layer covering the first optical layer and having a contact hole exposing a part of the contact electrode, wherein a sidewall of the contact hole has one or more steps.

According to one embodiment of the present disclosure, a tapered portion of the contact hole may have a taper angle of 50 to 70 degrees.

According to one embodiment of the present disclosure, the first electrode may include a plurality of conductive layers and a transparent conductive layer that is an uppermost layer, and the contact electrode may include a transparent conductive layer in an uppermost portion excluding a portion below the contact hole in contact with the second electrode along with the plurality of conductive layers.

According to one embodiment of the present disclosure, the plurality of conductive layers may include a first electrode conductive layer, a reflective conductive layer, and a second electrode conductive layer, and the transparent conductive layer includes indium tin oxide (ITO).

According to one embodiment of the present disclosure, insulating layers may be disposed between the light-emitting element and the optical layer and between the first electrode and the contact electrode.

According to one embodiment of the present disclosure, the insulating layer may have an opening spaced apart from a side surface of the contact hole of the optical layer.

According to one embodiment of the present disclosure, the display device may further include a third optical layer disposed on the second electrode on the plurality of light-emitting elements.

According to one embodiment of the present disclosure, the display device may further include a black matrix disposed on the second electrode including the third optical layer and having a plurality of transmissive holes; and a cover layer disposed on the black matrix.

According to one embodiment of the present disclosure, the circuit layer may further include a pixel driving circuit disposed on the substrate and electrically connected to the plurality of light-emitting elements and the contact electrode; and a plurality of signal lines electrically connecting the first electrode to the pixel driving circuit.

As described above, the various embodiments of the disclosed display device provide structural and material enhancements aimed at improving mechanical reliability and electrical performance, particularly in flexible and foldable applications. One of the features is the design of the contact hole structure between the contact electrode and the cathode, which reduces the risk of cracking by precisely controlling the spatial relationship between the insulating and optical layers. The display also incorporates interconnect patterns such as zigzag and sinusoidal configurations made from flexible conductive materials, which help distribute mechanical stress in areas that undergo bending.

The device includes a vertically stacked circuit configuration composed of multiple layers of organic insulation and conductive interconnections, allowing for high-density electrical routing while maintaining flexibility. Pixel driving is managed by external micro driver units, which simplifies the layout within each pixel. Additionally, the second electrode may be shared across multiple subpixels to reduce circuit complexity. To improve durability in bending regions, specific rigid layers are selectively omitted. These features collectively support high-performance operation in next-generation flexible display panels.

Although embodiments of the present disclosure have been described in more detail with reference to the accompanying drawings, the present disclosure is not necessarily limited to the embodiments, and various modifications may be carried out without departing from the technical spirit of the present disclosure.

Therefore, the embodiments disclosed in the present disclosure are not intended to limited the technical spirit of the present disclosure, but intended to describe the same, and the scope of the technical spirit of the present disclosure is not limited by these embodiments. Therefore, it should be understood that the above-described embodiments are illustrative and not restrictive in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a circuit layer on the substrate;
a plurality of banks on the circuit layer;
one or more light-emitting elements on the banks, each light-emitting element having a first electrode and a second electrode;
a contact electrode on the circuit layer to be spaced apart from the banks;
a first optical layer covering the banks and the one or more light-emitting elements on the banks; and
a second optical layer covering the first optical layer, the second optical layer having a contact hole exposing a part of the contact electrode,
wherein, when a distance between the bank and the first optical layer on a surface of the circuit layer is defined as a reference value of 1, a distance between the first optical layer and the contact hole on the surface of the circuit layer ranges from 0.5 to 2.5.

2. The display device of claim 1, wherein a sidewall of the contact hole has one or more steps.

3. The display device of claim 2, wherein each of the one or more steps is formed at a gentle angle.

4. The display device of claim 2, wherein each of the one or more steps includes a tapered portion and a horizontal portion adjusted according to a half tone mask.

5. The display device of claim 4, wherein the half tone mask includes a plurality of semi-transmissive layers, which include a plurality of semi-transmissive patterns.

6. The display device of claim 5, wherein gaps between the plurality of semi-transmissive patterns are formed to gradually increase toward central portions of the plurality of semi-transmissive layers.

7. The display device of claim 1, wherein the first electrode includes a plurality of conductive layers and a transparent conductive layer that is an uppermost layer, and the contact electrode includes a transparent conductive layer in an uppermost portion, except at a portion below the contact hole, where the second electrode is in contact with the plurality of conductive layers.

8. The display device of claim 7, wherein the plurality of conductive layers of the first electrode includes a first electrode conductive layer, a reflective conductive layer, and a second electrode conductive layer, and the transparent conductive layer of the first electrode includes a transparent conductive oxide.

9. The display device of claim 1, wherein insulating layers are between the light-emitting element and the second optical layer and between the first electrode and the contact electrode.

10. The display device of claim 9, wherein the insulating layer has an opening spaced apart from a side surface of the contact hole of the second optical layer.

11. The display device of claim 1, further comprising a third optical layer on the second electrode on the plurality of light-emitting elements.

12. The display device of claim 11, further comprising:
a black matrix on the second electrode including the third optical layer and having a plurality of transmissive holes; and
a cover layer on the black matrix.

13. The display device of claim 1, wherein the circuit layer further includes:
a pixel driving circuit on the substrate and electrically connected to the plurality of light-emitting elements and the contact electrode; and
a plurality of signal lines electrically connecting the first electrode to the pixel driving circuit.

14. A display device comprising:
a substrate;
a circuit layer on the substrate;
a plurality of banks on the circuit layer;
one or more light-emitting elements on the banks and each having a first electrode and a second electrode;
a contact electrode on the circuit layer and spaced apart from the plurality of banks;
a first optical layer covering the banks and the one or more light-emitting elements disposed on the banks; and
a second optical layer covering the first optical layer and having a contact hole exposing a part of the contact electrode,
wherein a sidewall of the contact hole has one or more steps.

15. The display device of claim 14, wherein each of the one or more steps is formed at a gentle angle.

16. The display device of claim 14, wherein each of the one or more steps includes a tapered portion and a horizontal portion adjusted according to a half tone mask.

17. The display device of claim 16, wherein the half tone mask includes a plurality of semi-transmissive layers, which include a plurality of semi-transmissive patterns.

18. The display device of claim 17, wherein gaps between the plurality of semi-transmissive patterns are formed to gradually increase toward central portions of the plurality of semi-transmissive layers.

19. The display device of claim 15, wherein the first electrode includes a plurality of conductive layers and a transparent conductive layer that is an uppermost layer, and the contact electrode includes a transparent conductive layer in an uppermost portion, except at a portion below the contact hole, where the second electrode is in contact with the plurality of conductive layers.

20. The display device of claim 19, wherein the plurality of conductive layers of the first electrode includes a first electrode conductive layer, a reflective conductive layer, and a second electrode conductive layer, and the transparent conductive layer of the first electrode includes a transparent conductive oxide (ITO).
